(19) United States
(12) Patent Application Publication
(10) Pub. No.: US 2025/0072109 A1
(43) Pub. Date: Feb. 27, 2025

(54) SEMICONDUCTOR DEVICE AND METHOD OF MANUFACTURING THE SAME

(71) Applicant: INNOSCIENCE (SUZHOU) SEMICONDUCTOR CO., LTD., Jiangsu (CN)

(72) Inventors: Sichao LI, Guangdong (CN); Hui YAN, Guangdong (CN); Chunhua ZHOU, Guangdong (CN)

(73) Assignee: INNOSCIENCE (SUZHOU) SEMICONDUCTOR CO., LTD., Jiangsu (CN)

(21) Appl. No.: 18/576,363

(22) PCT Filed: Sep. 16, 2022
(86) PCT No.: PCT/CN2022/119358

§ 371 Date: Jan. 4, 2024

(51) Int. Cl. H01L 27/098; H01L 21/8252; H01L 23/48; H01L 29/778

(52) U.S. Cl. CPC H01L 27/098; H01L 21/8252; H01L 23/481; H01L 29/7786

(57) ABSTRACT

A semiconductor device includes: a substrate; a first nitride semiconductor layer on the substrate; a second nitride semiconductor layer on the first nitride semiconductor layer; a drain contact and a source contact on the second nitride semiconductor layer; a common contact on the second nitride semiconductor layer and between the drain contact and source contact; a first gate structure on the second nitride semiconductor layer and between the drain contact and common contact; a second gate structure on the second nitride semiconductor layer and between the common contact and source contact; a conductive wire on the source contact; a dielectric layer on the second nitride semiconductor layer and covering a portion of a lateral surface of the conductive wire; and a conductive via connected to the conductive wire, extending through a portion of the dielectric layer, the second nitride semiconductor layer, and the first nitride semiconductor layer to the substrate.

### BACKGROUND

### 1. Technical Field

The present disclosure relates to a semiconductor device and a method of manufacturing a semiconductor device.

### 2. Description of the Related Art

Components including direct bandgap semiconductors, for example, semiconductor components including group III-V materials or group III-V compounds (Category: III-V compounds) can operate or work under a variety of conditions or in a variety of environments (e.g., at different voltages and frequencies) due to their characteristics.

The semiconductor components may include a heterojunction bipolar transistor (HBT), a heterojunction field effect transistor (HFET), a high-electron-mobility transistor (HEMT), a modulation-doped FET (MODFET) and the like.

### SUMMARY

In some embodiments of the present disclosure, a semiconductor device is provided. The semiconductor device includes: a substrate; a first nitride semiconductor layer on the substrate; a second nitride semiconductor layer on the first nitride semiconductor layer and having a band gap greater than a band gap of the first nitride semiconductor layer; a drain contact on the second nitride semiconductor layer; a source contact on the second nitride semiconductor layer; a common contact between the drain contact and the source contact; a first gate structure between the drain contact and the common contact; a second gate structure between the common contact and the source contact; a conductive wire on the source contact; a dielectric layer disposed on the second nitride semiconductor layer and covering at least a portion of a lateral surface of the conductive wire; and a conductive via connected to the conductive wire, wherein the conductive via extends through a portion of the dielectric layer, the second nitride semiconductor layer, and the first nitride semiconductor layer to the substrate.

In some embodiments of the present disclosure, a method of manufacturing a semiconductor device is provided. The method includes: providing a substrate; forming a first nitride semiconductor layer on the substrate; forming a second nitride semiconductor layer on the first nitride semiconductor layer, wherein the second nitride semiconductor layer has a band gap greater than a band gap of the first nitride semiconductor layer; forming a drain contact and a source contact on the second nitride semiconductor layer; forming a common contact between the drain contact and the source contact; forming a first gate structure between the drain contact and the common contact; forming a second gate structure between the common contact and the source contact; forming a conductive wire on the source contact; forming a dielectric layer on the second nitride semiconductor layer, wherein the dielectric layer covers at least a portion of the conductive wire; and forming a conductive via connected to the conductive wire, wherein the conductive via extends through a portion of the dielectric layer, the second nitride semiconductor layer, and the first nitride semiconductor layer to the substrate.

In some embodiments of the present disclosure, a semiconductor device is provided. The semiconductor device includes: a substrate; a first nitride semiconductor layer on the substrate; a second nitride semiconductor layer on the first nitride semiconductor layer and having a band gap greater than a band gap of the first nitride semiconductor layer; a drain contact on the second nitride semiconductor layer; a source contact on the second nitride semiconductor layer; a common contact between the drain contact and the source contact; a first gate structure between the drain contact and the common contact; and a second gate structure between the common contact and the source contact, wherein the source contact is electrically connected to the substrate through a conductive via, and a shortest distance between the first gate structure and the common contact is smaller than a shortest distance between the second gate structure and the common contact

In some embodiments of the present disclosure, a semiconductor device is provided. The semiconductor device includes: a substrate including an insulating layer buried in the substrate, the substrate having a first region and a second region; a first nitride semiconductor layer on the substrate; a second nitride semiconductor layer on the first nitride semiconductor layer and having a band gap greater than a band gap of the first nitride semiconductor layer; an isolation structure disposed between the first region and the second region of the substrate and extending through the second nitride semiconductor layer and the first nitride semiconductor layer to the insulating layer, a first source contact and a first drain contact on the second nitride semiconductor layer on the first region of the substrate; and a first gate structure between the first source contact and the first drain contact; a second source contact and a second drain contact on the second nitride semiconductor layer on the second region of the substrate; a second gate structure between the second source contact and the second drain contact; and a first conductive wire disposed on and connecting the first source contact and the second drain contact.

In some embodiments of the present disclosure, a method of manufacturing a semiconductor device is provided. The method includes: providing a substrate comprising an insulating layer buried in the substrate, the substrate having a first region and a second region; forming a first nitride semiconductor layer on the substrate; forming a second nitride semiconductor layer on the first nitride semiconductor layer, wherein the second nitride semiconductor layer has a band gap greater than a band gap of the first nitride semiconductor layer; forming an isolation structure between the first region and the second region of the substrate, the isolation structure extending through the second nitride semiconductor layer and the first nitride semiconductor layer to the insulating layer; forming a first source contact and a first drain contact on the second nitride semiconductor layer on the first region of the substrate; forming a first gate structure between the first source contact and the first drain contact; forming a second source contact and a second drain contact on the second nitride semiconductor layer on the second region of the substrate; forming a second gate structure between the second source contact and the second drain contact; and forming a first conductive wire on the first source contact and the second drain contact, wherein the first conductive wire connects the first source contact and the second drain contact.

In some embodiments of the present disclosure, a semiconductor device is provided. The semiconductor device includes: a substrate comprising an insulating layer buried in the substrate, the substrate having a first region and a second region; a first nitride semiconductor layer on the substrate; a second nitride semiconductor layer on the first nitride semiconductor layer and having a band gap greater than a band gap of the first nitride semiconductor layer; an isolation structure surrounding the first region of the substrate; a first source contact and a first drain contact on the second nitride semiconductor layer on the first region of the substrate; and a first gate structure between the first source contact and the first drain contact; a second source contact and a second drain contact on the second nitride semiconductor layer on the second region of the substrate; a second gate structure between the second source contact and the second drain contact; and a first conductive wire disposed on and connecting the first source contact and the second drain contact, wherein a projection of the first conductive wire perpendicular to an upper surface of the substrate overlaps the isolation structure.

In some embodiments of the present disclosure, a semiconductor device is provided. The semiconductor device includes: a substrate having a first region and a second region; a first doped region in the first region of the substrate, wherein the first doped region has opposite polarity to the substrate; a second doped region in the second region of the substrate, wherein the second doped region has opposite polarity to the substrate; a first nitride semiconductor layer on the substrate; a second nitride semiconductor layer on the first nitride semiconductor layer and having a band gap greater than a band gap of the first nitride semiconductor layer; an isolation structure disposed between the first region and the second region of the substrate and extending through the second nitride semiconductor layer and the first nitride semiconductor layer to the substrate; a first source contact and a first drain contact on the second nitride semiconductor layer on the first region of the substrate; a first gate structure between the first source contact and the first drain contact; a second source contact and a second drain contact on the second nitride semiconductor layer on the second region of the substrate; a second gate structure between the second source contact and the second drain contact; and a first conductive wire disposed on and connecting the first source contact and the second drain contact.

In some embodiments of the present disclosure, a method of manufacturing a semiconductor device is provided. The method includes: providing a substrate having a first region and a second region; forming a first doped region in the first region of the substrate, wherein the first doped region has opposite polarity to the substrate; forming a second doped region in the second region of the substrate, wherein the second doped region has opposite polarity to the substrate; forming a first nitride semiconductor layer on the substrate; forming a second nitride semiconductor layer on the first nitride semiconductor layer, wherein the second nitride semiconductor layer has a band gap greater than a band gap of the first nitride semiconductor layer; forming an isolation structure between the first region and the second region of the substrate, the isolation structure extending through the second nitride semiconductor layer and the first nitride semiconductor layer to the substrate; forming a first source contact and a first drain contact on the second nitride semiconductor layer on the first region of the substrate; forming a first gate structure between the first source contact and the first drain contact; forming a second source contact and a second drain contact on the second nitride semiconductor layer on the second region of the substrate; and forming a second gate structure between the second source contact and the second drain contact; and forming a first conductive wire on the first source contact and the second drain contact, wherein the first conductive wire connects the first source contact and the second drain contact.

In some embodiments of the present disclosure, a semiconductor device is provided. The semiconductor device includes: a substrate having a first region and a second region; a first doped region in the first region of the substrate, wherein the first doped region has opposite polarity to the substrate; a second doped region in the second region of the substrate, wherein the second doped region has opposite polarity to the substrate; a first nitride semiconductor layer on the substrate; a second nitride semiconductor layer on the first nitride semiconductor layer and having a band gap greater than a band gap of the first nitride semiconductor layer; an isolation structure surrounding the first doped region; a first source contact and a first drain contact on the second nitride semiconductor layer on the first region of the substrate; and a first gate structure between the first source contact and the first drain contact; a second source contact and a second drain contact on the second nitride semiconductor layer on the second region of the substrate; and a second gate structure between the second source contact and the second drain contact; and a first conductive wire disposed on and connecting the first source contact and the second drain contact, wherein a projection of the first conductive wire perpendicular to an upper surface of the substrate overlaps the isolation structure.

In some embodiments of the present disclosure, a semiconductor device is provided. The semiconductor device includes: a substrate having a first region and a second region; a doped semiconductor layer on the first region and the second region of the substrate, wherein the doped semiconductor layer is doped with opposite polarity to the substrate; a first nitride semiconductor layer on the doped semiconductor layer; a second nitride semiconductor layer on the first nitride semiconductor layer and having a band gap greater than a band gap of the first nitride semiconductor layer; an isolation structure disposed between the first region and the second region of the substrate and extending through the second nitride semiconductor layer, the first nitride semiconductor layer and the doped semiconductor layer to the substrate; a first source contact and a first drain contact on the second nitride semiconductor layer on the first region of the substrate; and a first gate structure between the first source contact and the first drain contact; a second source contact and a second drain contact on the second nitride semiconductor layer on the second region of the substrate; a second gate structure between the second source contact and the second drain contact; and a first conductive wire disposed on and connecting the first source contact and the second drain contact.

In some embodiments of the present disclosure, a method of manufacturing a semiconductor device is provided. The method includes: providing a substrate having a first region and a second region; forming a doped semiconductor layer on the first region and the second region of the substrate, wherein the doped semiconductor layer is doped with opposite polarity to the substrate; forming a first nitride semiconductor layer on the doped semiconductor layer; forming a second nitride semiconductor layer on the first nitride semiconductor layer, wherein the second nitride semiconductor layer has a band gap greater than a band gap of the first nitride semiconductor layer; forming an isolation structure between the first region and the second region of the substrate, the isolation structure extending through the second nitride semiconductor layer, the first nitride semiconductor layer and the doped semiconductor layer to the substrate; forming a first source contact and a first drain contact on the second nitride semiconductor layer on the first region of the substrate; forming a first gate structure between the first source contact and the first drain contact; forming a second source contact and a second drain contact on the second nitride semiconductor layer on the second region of the substrate; and forming a second gate structure between the second source contact and the second drain contact; and forming a first conductive wire on the first source contact and the second drain contact, wherein the first conductive wire connects the first source contact and the second drain contact.

In some embodiments of the present disclosure, a semiconductor device is provided. The semiconductor device includes: a substrate having a first region and a second region; a doped semiconductor layer on the first region and the second region of the substrate, wherein the doped semiconductor layer is doped with opposite polarity to the substrate; a first nitride semiconductor layer on the doped semiconductor layer; a second nitride semiconductor layer on the first nitride semiconductor layer and having a band gap greater than a band gap of the first nitride semiconductor layer; an isolation structure surrounding the first region of the substrate; a first source contact and a first drain contact on the second nitride semiconductor layer on the first region of the substrate; a first gate structure between the first source contact and the first drain contact; a second source contact and a second drain contact on the second nitride semiconductor layer on the second region of the substrate; a second gate structure between the second source contact and the second drain contact; and a first conductive wire disposed on and connecting the first source contact and the second drain contact, wherein a projection of the first conductive wire perpendicular to an upper surface of the substrate overlaps the isolation structure.

According to some embodiments of the present disclosure, the semiconductor device integrates a high-side transistor and a low-side transistor on a single substrate. Parasitic resistance and parasitic inductance resulting from the conductive wire are reduced. The performance of the semiconductor device is improved. In addition, the semiconductor device is miniaturized.

### BRIEF DESCRIPTION OF THE DRAWINGS

Aspects of the present disclosure are readily understood from the following detailed description when read with the accompanying figures. It should be noted that various features may not be drawn to scale. In fact, the dimensions of the various features may have arbitrarily increased or reduced for clarity of discussion.

FIG. 1 is a schematic circuit diagram in accordance with some embodiments of the present disclosure.

FIG. 2 illustrates a top view of a semiconductor device in accordance with some comparative embodiments of the present disclosure.

FIG. 3 illustrates a top view of a portion of a semiconductor device in accordance with some comparative embodiments of the present disclosure.

FIG. 4 illustrates a cross-sectional view of a portion of a semiconductor device taken along line A-A′ shown in FIG. 3 in accordance with some comparative embodiments of the present disclosure.

FIG. 5 illustrates a top view of a semiconductor device in accordance with some embodiments of the present disclosure.

FIG. 6 illustrates a top view of a semiconductor device in accordance with some embodiments of the present disclosure.

FIG. 7 illustrates a top view of a semiconductor device in accordance with some embodiments of the present disclosure.

FIG. 8 illustrates a top view of a portion of a semiconductor device in accordance with some embodiments of the present disclosure.

FIG. 9 illustrates a cross-sectional view of a portion of a semiconductor device taken along line B-B′ shown in FIG. 8 in accordance with some embodiments of the present disclosure.

FIG. 10 illustrates a top view of a portion of a semiconductor device in accordance with some embodiments of the present disclosure.

FIG. 11 illustrates a cross-sectional view of a portion of a semiconductor device taken along line C-C′ shown in FIG. 10 in accordance with some embodiments of the present disclosure.

FIG. 12 illustrates a cross-sectional view of a portion of a semiconductor device taken long line D-D′ shown in FIG. 10 in accordance with some embodiments of the present disclosure.

FIG. 13 illustrates a bottom view of a portion of a semiconductor device shown in FIG. 11 and FIG. 12 in accordance with some embodiments of the present disclosure.

FIG. 14 illustrates a cross-sectional view of a portion of a semiconductor device taken along line C-C′ shown in FIG. 10 in accordance with some embodiments of the present disclosure.

FIG. 15 illustrates a cross-sectional view of a portion of a semiconductor device taken along line D-D′ shown in FIG. 10 in accordance with some embodiments of the present disclosure.

FIG. 16 illustrates a bottom view of a portion of a semiconductor device shown in FIG. 14 and FIG. 15 in accordance with some embodiments of the present disclosure.

FIG. 17 illustrates a cross-sectional view of a portion of a semiconductor device taken along line C-C′ shown in FIG. 10 in accordance with some embodiments of the present disclosure.

FIG. 18 illustrates a cross-sectional view of a portion of a semiconductor device taken along line D-D′ shown in FIG. 10 in accordance with some embodiments of the present disclosure.

FIG. 19 illustrates a bottom view of a portion of a semiconductor device shown in FIG. 17 and FIG. 18 in accordance with some embodiments of the present disclosure.

FIG. 20A, FIG. 20B, and FIG. 20C illustrate some operations to manufacture a semiconductor device in accordance with some embodiments of the present disclosure.

FIG. 21A, FIG. 21B, FIG. 21C, FIG. 21D, FIG. 21E, FIG. 21F and FIG. 21G illustrate some operations to manufacture a semiconductor device in accordance with some embodiments of the present disclosure.

FIG. 22A, FIG. 22B, FIG. 22C, FIG. 22D, FIG. 22E, FIG. 22F and FIG. 22G illustrate some operations to manufacture a semiconductor device in accordance with some embodiments of the present disclosure.

FIG. 23A, FIG. 23B, FIG. 23C, FIG. 23D, FIG. 23E, FIG. 23F and FIG. 23G illustrate some operations to manufacture a semiconductor device in accordance with some embodiments of the present disclosure.

### DETAILED DESCRIPTION

The following disclosure provides for many different embodiments, or examples, for implementing different features of the provided subject matter. Specific examples of components and arrangements are described below. These are, of course, merely examples and are not intended to be limiting. In the present disclosure, reference to the formation of a first feature over or on a second feature in the description that follows may include embodiments in which the first and second features are formed in direct contact, and may also include embodiments in which additional features may have formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Common reference numerals are used throughout the drawings and the detailed description to indicate the same or similar components. Embodiments of the present disclosure will be readily understood from the following detailed description taken in conjunction with the accompanying drawings.

Embodiments of the present disclosure are discussed in detail below. It should be appreciated, however, that the present disclosure provides many applicable concepts that can be embodied in a wide variety of specific contexts. The specific embodiments discussed are merely illustrative and do not limit the scope of the disclosure.

In the present disclosure, an upper surface of a substrate refers to a surface of the substrate on which another element(s) (such as a layer(s)) is disposed. In the present disclosure, a lower surface of an element refers to a surface of the element facing the substrate. In the present disclosure, an upper surface of an element refers to a surface of the element facing away the substrate. In some embodiments, a lower surface of an element refers to a surface of the element relatively close to the substrate in comparison with an upper surface of the element. In the present disclosure, a lateral surface of an element refers to a surface of the element connecting the upper surface and the lower surface of the element. In some embodiments, a lateral surface of an element refers to a surface of the element connecting the upper surface and the lower surface of the element in a cross-sectional view.

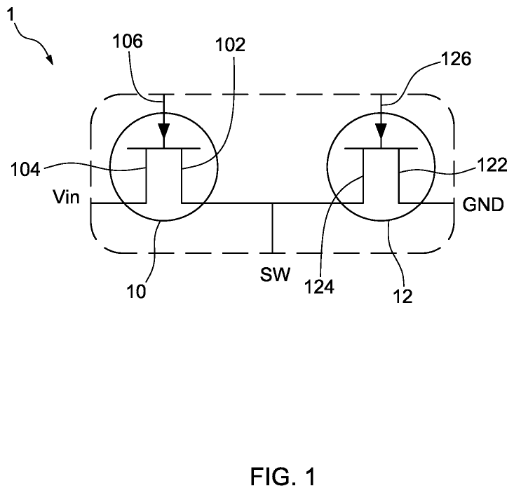

FIG. 1 is a schematic circuit diagram in accordance with some embodiments of the present disclosure. The schematic circuit diagram of FIG. 1 shows a half-bridge circuit 1. The half-bridge circuit 1 includes a transistor 10 and a transistor 12. The transistor 10 and the transistor 12 are electrically connected in series. The transistor 10 includes a source terminal 102, a drain terminal 104 and a gate terminal 106. The transistor 12 includes a source terminal 122, a drain terminal 124 and a gate terminal 126. The source terminal 102 of the transistor 10 and the drain terminal 124 of the transistor 12 are connected to the same potential at a switch node (SW). The drain terminal 104 of the transistor 10 is connected to a voltage supply (Vᵢₙ). The source terminal 122 of the transistor 12 is connected to ground (GND). The transistor 10 may be referred to as a high-side (HS) transistor. The transistor 12 may be referred to as a low-side (LS) transistor.

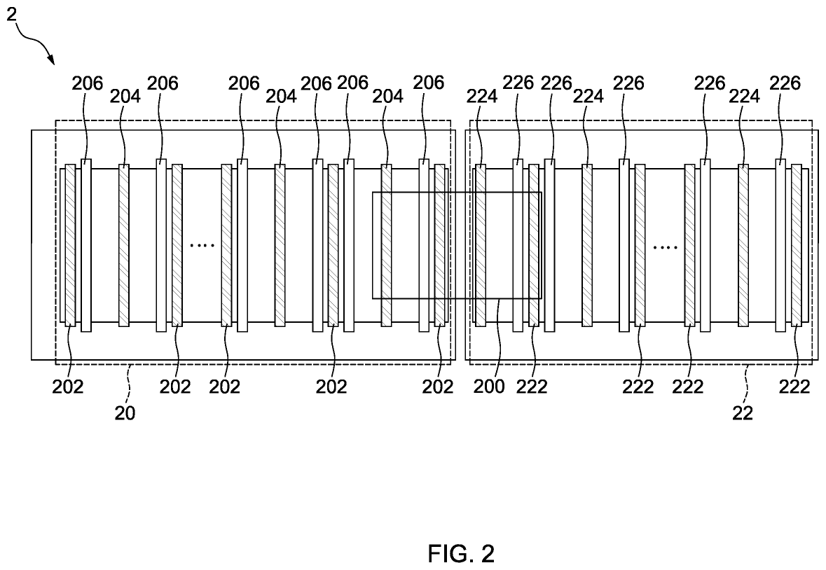

FIG. 2 illustrates a top view of a semiconductor device 2 in accordance with some comparative embodiments of the present disclosure. The semiconductor device 2 includes a device region 20 and a device region 22. The device region 20 and the device region 22 are formed on two separate substrates, respectively. The device region 20 includes source contacts 202, drain contacts 204 and gate contacts 206. The source contacts 202, the drain contacts 204 and the gate contacts 206 are arranged interdigitatedly in the device region 20. A set of one source contact 202, one neighboring gate contact 206 and one neighboring drain contact 204 corresponds to one transistor. A plurality of the transistors are electrically connected in parallel in the device region 20 to overall function as the transistor 10 shown in FIG. 1.

The device region 22 includes source contacts 222, drain contacts 224 and gate contacts 226. The source contacts 222, the drain contacts 224 and the gate contacts 226 are arranged interdigitatedly in the device region 22. A set of one source contact 222, one neighboring gate contact 226 and one neighboring drain contact 224 corresponds to one transistor. A plurality of the transistors are electrically connected in parallel in the device region 22 to overall function as the transistor 22 shown in FIG. 1.

Still referring to FIG. 2, the source contacts 202 of the device region 20 and the drain contacts 224 of the device region 22 are electrically connected to the same potential at a switch node (SW). The drain contacts 204 of the device region 20 are electrically connected to a voltage supply (Vᵢₙ). The source contacts 222 of the device region 22 are electrically connected to ground (GND).

The semiconductor device 2 includes the device region 20 functioning as the transistor 10 shown in FIG. 1 and the device region 22 functioning as the transistor 12 shown in FIG. 1 to build a half-bridge circuit. The device region 20 may be referred to as a high-side device region. The device region 22 may be referred to as a low-side device region.

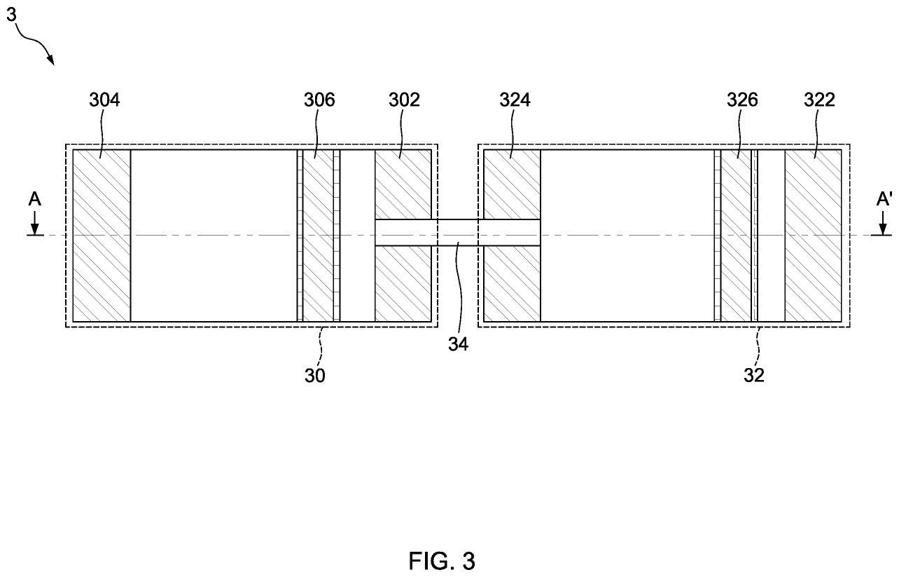

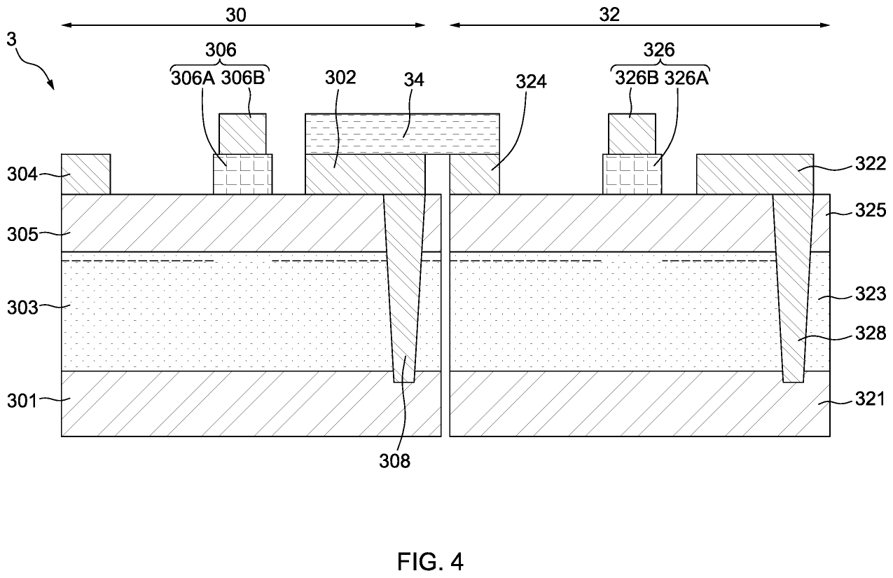

FIG. 3 illustrates a top view of a portion of a semiconductor device 3 in accordance with some comparative embodiments of the present disclosure. In some embodiments, FIG. 3 illustrates an enlarged view of a portion 200 of the semiconductor device 2 shown in FIG. 2. FIG. 4 illustrates a cross-sectional view of a portion of a semiconductor device 3 taken along line A-A′ shown in FIG. 3 in accordance with some comparative embodiments of the present disclosure. The semiconductor device 3 includes a device region 30 and a device region 32. As shown in FIG. 4, the device region 30 includes a substrate 301, a semiconductor layer 303 on the substrate 301, and a semiconductor layer 305 on the semiconductor layer 303. The semiconductor layer 305 has a band gap greater than a band gap of the semiconductor layer 303. The device region 30 also includes a source contact 302, a drain contact 304 and a gate structure 306 between the source contact 302 and drain contact 304 on the semiconductor layer 305. The device region 32 includes a substrate 321, a semiconductor layer 323 on the substrate 321, and a semiconductor layer 325 on the semiconductor layer 323. The semiconductor layer 325 has a band gap greater than a band gap of the semiconductor layer 323. The device region 32 also includes a source contact 322, a drain contact 324 and a gate structure 326 between the source contact 322 and drain contact 324 on the nitride semiconductor layer 325. The substrate 301 and the substrate 321 are separate substrates.

As shown in FIG. 4, the gate structure 306 includes a doped semiconductor element 306A and a gate contact 306B on the doped semiconductor element 306A. The gate structure 326 includes a doped semiconductor element 326A and a gate contact 326B on the doped semiconductor element 326A. The device region 30 further includes a conductive via 308 connecting the source contact 302 to the substrate 301. The device region 32 further includes a conductive via 328 connecting the source contact 322 to the substrate 321.

Referring to FIG. 3 and FIG. 4, the source contact 302 of the device region 30 and the drain contact 324 of the device region 32 are electrically connected to the same potential at a switch node (SW) by a conductive wire 34.

The drain contact 304 of the device region 30 is electrically connected to a voltage supply (Vᵢₙ). The source contact 322 of the device region 32 is electrically connected to ground (GND). The semiconductor device 3 includes the device region 30 functioning as the transistor 10 shown in FIG. 1 and the device region 32 functioning as the transistor 12 shown in FIG. 1 to form a half-bridge circuit. The device region 30 may be referred to as a high-side device region. The device region 32 may be referred to as a low-side device region.

In the semiconductor device 3, the circuit of the transistor 10 shown in FIG. 1 is formed on the substrate 301 and corresponds to the device region 30. The circuit of the transistor 12 shown in FIG. 1 is formed on the substrate 302 and corresponds to the device region 32. The substrate 301 and the substrate 302 are separate substrates. The conductive wire 34 bridges the device region 30 and the device region 32. The conductive wire 34 may introduce parasitic resistance or parasitic inductance, resulting in spike or surge in the voltage (Vas) between the source and the drain during switching on and off at high speed. The voltage spike or surge may damage the semiconductor device 3. To address the issue of voltage spike or surge, the semiconductor device 3 can be designed so as to withstand a higher voltage than an input voltage. For example, for an input voltage of 10V, the semiconductor device 3 can be designed as if it is for an input voltage of 20V. However, such design may compromise the performance of the semiconductor device and cause loss. In addition, the conductive wire 34 may take a relatively large area, resulting in a relatively large size of the semiconductor device.

The present disclosure relates to semiconductor devices and methods of manufacturing semiconductor devices. In some embodiments, the semiconductor devices integrate a half-bridge circuit on a single substrate. Therefore, the conductive wire connecting a high-side transistor and a low-side transistor can be made with a smaller dimension (e.g., a smaller length). As a result, the issue of the voltage spike or surge can be alleviated and the miniaturization of the semiconductor devices can be improved.

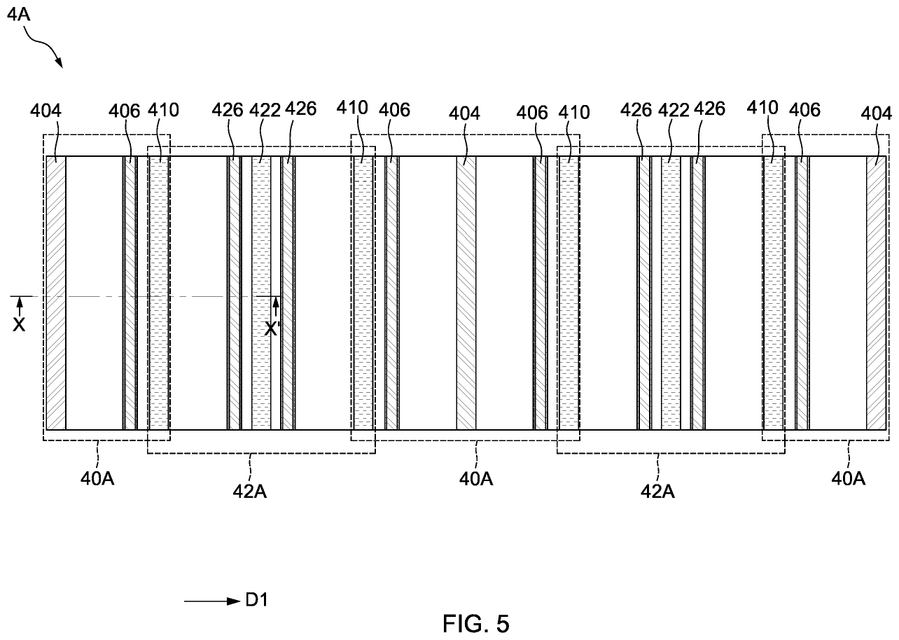

FIG. 5 illustrates a top view of a semiconductor device 4A in accordance with some embodiments of the present disclosure. The semiconductor device 4A includes high-side device regions 40A and low-side device regions 42A on a single substrate. The high-side device regions 40A and the low-side device regions 42A are alternately arranged in a direction D1. Each of the high-side device regions 40A includes one or more drain contacts 404, one or more contacts 410 and one or more gate structures 406. Each of the low-side device regions 42A includes one or more contacts 410, one or more source contacts 422, and one or more gate structures 426. The drain contacts 404 and the contacts 410 are arranged interdigitatedly in the direction D1. The contacts 410 and the source contacts 422 are arranged interdigitatedly in the direction D1. A high-side device region 40A and a neighboring low-side device region 42A share the contacts 410. The contacts 410 serve as source contacts to the drain contacts 404 in the high-side device region 40A. The contacts 410 serve as drain contacts to the source contacts 422 in the low-side device region 42A. The high-side device region 40A functions as the transistor 10 shown in FIG. 1. The low-side device region 42A functions as the transistor 12 shown in FIG. 1. The drain contacts 404 of the high-side device regions 40A are electrically connected to a voltage supply (Vᵢₙ). The source contacts 422 of the low-side device regions 42A are electrically connected to ground (GND).

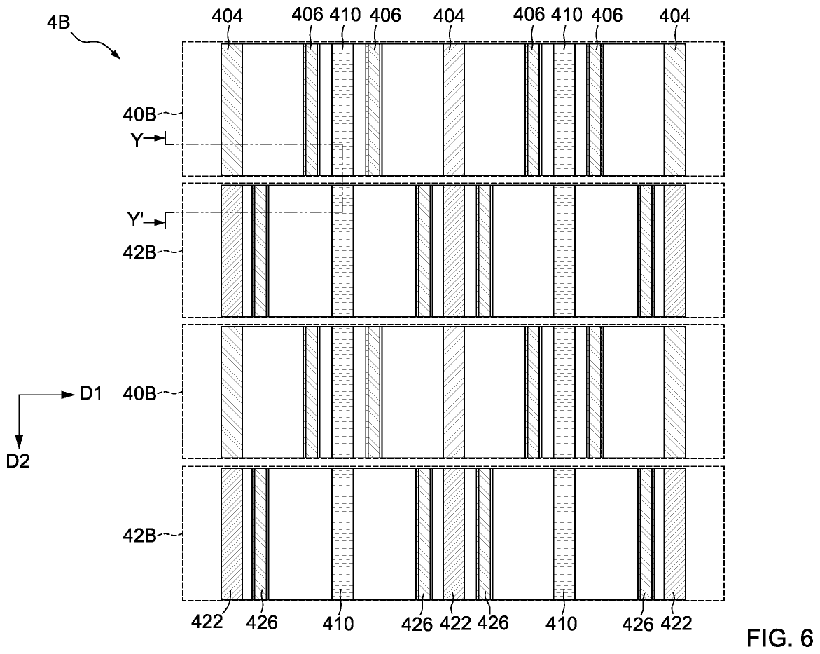

FIG. 6 illustrates a top view of a semiconductor device 4B in accordance with some embodiments of the present disclosure. FIG. 6 shows an alternative layout to that shown in FIG. 5. The semiconductor device 4B includes high-side device regions 40B and low-side device regions 42B on a single substrate. The high-side device regions 40B and the low-side device regions 42B are alternately arranged in a direction D2 substantially perpendicular to the direction D1. The high-side device region 40B includes a plurality of transistors electrically connected with each other in parallel, and each transistor includes a drain contact 404, a contact 410 and a gate structure 406. The low-side device region 42B includes a plurality of transistors electrically connected with each other in parallel, and each transistor includes a contact 410, a source contact 422 and a gate structure 426. The contacts 410 serve as source contacts to the drain contacts 404 in the high-side device region 40B. The contacts 410 serve as drain contacts to the source contacts 422 in the low-side device region 42B. In some embodiments, the drain contacts 404 are electrically connected with each other and to a voltage supply (Vᵢₙ), for example, by an overlying conductive layer (e.g., a metallization layer referred to as M1). In some embodiments, the source contacts 422 are electrically connected with each other and to ground (GND), for example, by an overlying conductive layer (e.g., a metallization layer referred to as M2). In some embodiments, the contacts 410 are electrically connected with each other to a switch node, for example, by an overlying conductive layer (e.g., a metallization layer referred to as M3).

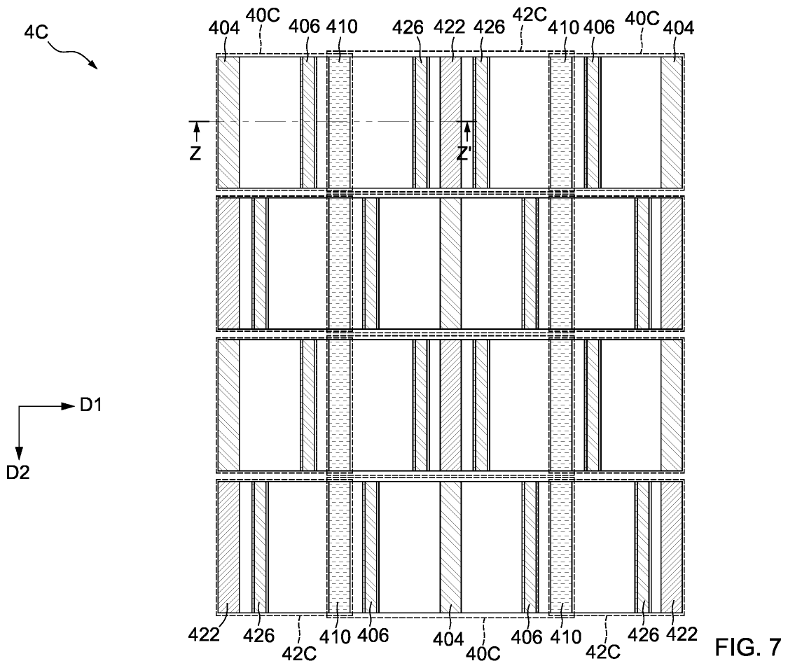

FIG. 7 illustrates a top view of a semiconductor device 4C in accordance with some embodiments of the present disclosure. FIG. 7 shows an alternative layout to that shown in FIG. 6. The semiconductor device 4C includes high-side device regions 40C and low-side device regions 42C on a single substrate. The semiconductor device 4C is substantially the same as the semiconductor device 4B, except that the high-side device regions 40C and the low-side device regions 42C are alternately arranged in the direction D1 and in the direction D2.

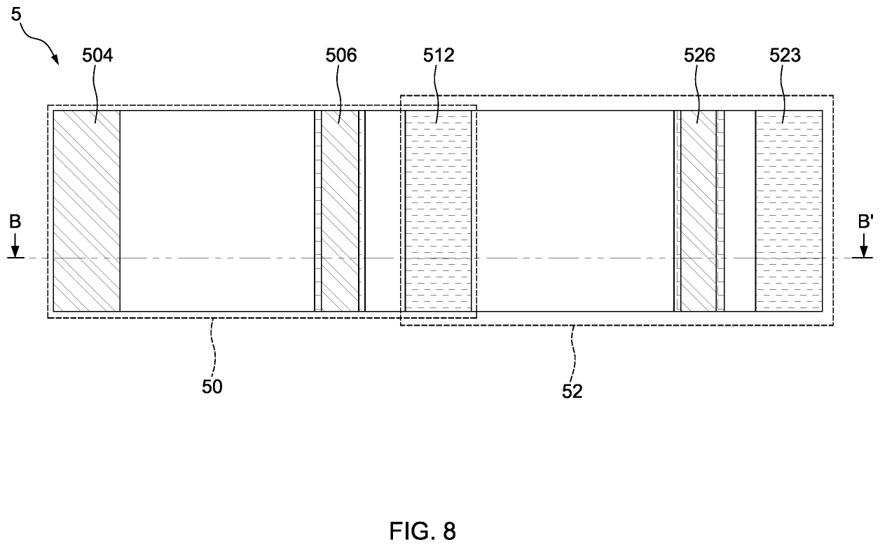

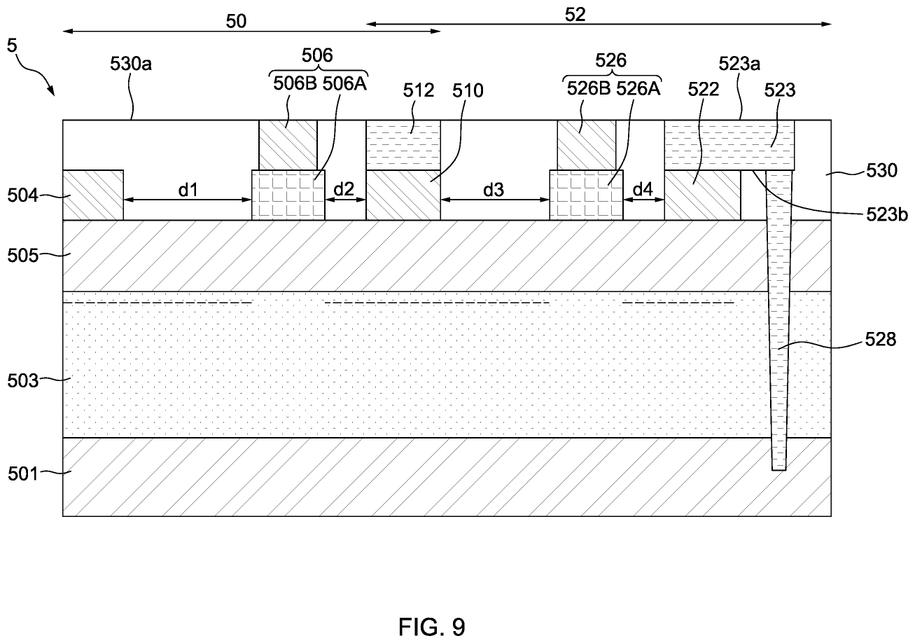

FIG. 8 illustrates a top view of a portion of a semiconductor device 5 in accordance with some embodiments of the present disclosure. FIG. 9 illustrates a cross-sectional view of a portion of a semiconductor device 5 taken along line B-B′ shown in FIG. 8 in accordance with some embodiments of the present disclosure. In some embodiments, FIG. 9 may illustrate a cross-sectional view of a portion of the semiconductor device 4A taken along line X-X′ shown in FIG. 5. In some embodiments, FIG. 9 may illustrate a cross-sectional view of a portion of the semiconductor device 4B taken along line Y-Y′ shown in FIG. 6. In some embodiments, FIG. 9 may illustrate a cross-sectional view of a portion of the semiconductor device 4C taken along line Z-Z′ shown in FIG. 7. As shown in FIG. 9, the semiconductor device 5 includes a substrate 501, a semiconductor layer 503, a semiconductor layer 505, contacts 504, 510, 522, and gate structures 506, 526.

The substrate 501 may include, for example, but is not limited to, silicon (Si), doped silicon (doped Si), silicon carbide (SiC), germanium silicide (SiGe), gallium arsenide (GaAs), or other semiconductor materials. In some embodiments, the substrate 501 may include an intrinsic semiconductor material. In some embodiments, the substrate 501 may include a p-type semiconductor material. In some embodiments, the substrate 501 may include a silicon layer doped with boron (B). In some embodiments, the substrate 501 may include a silicon layer doped with gallium (Ga). In some embodiments, the substrate 501 may include an n-type semiconductor material. In some embodiments, the substrate 501 may include a silicon layer doped with arsenic (As). In some embodiments, the substrate 501 may include a silicon layer doped with phosphorus (P). In some embodiments, the substrate 501 may further include a doped region, such as a p-well, an n-well, or the like. In some embodiments, the substrate 501 may include, for example, but is not limited to, sapphire, silicon on insulator (SOI), or other suitable materials.

The semiconductor layer 503 is formed on the substrate 501. In some embodiments, the semiconductor layer 503 may include, for example, but is not limited to, a group III-V material. In some embodiments, the semiconductor layer 503 may include, for example, but is not limited to, a nitride semiconductor material. In some embodiments, the semiconductor layer 503 may include, for example, but is not limited to, a group III nitride material. In some embodiments, the semiconductor layer 503 may include, for example, but is not limited to, a compound InₓAl_{y}Ga_{1-x-y}N, where x+y≤1. In some embodiments, the semiconductor layer 503 may include, for example, but is not limited to, a compound Al_{y}Ga_{(1-y)}N, where 0<y<1.

The semiconductor layer 505 is formed on the semiconductor layer 503. In some embodiments, the semiconductor layer 505 may include, for example, but is not limited to, a group III-V material. In some embodiments, the semiconductor layer 505 may include, for example, but is not limited to, a nitride semiconductor material. In some embodiments, the semiconductor layer 505 may include, for example, but is not limited to, a group III nitride material. In some embodiments, the semiconductor layer 505 may include, for example, but is not limited to, a compound InₓAl_{y}Ga_{1-x-y}N, where x+y≤1. In some embodiments, the semiconductor layer 505 may include, for example, but is not limited to, a compound Al_{y}Ga_{(1-y)}N, where (<y<1.

In some embodiments, a heterojunction is formed between the semiconductor layer 503 and the semiconductor layer 505. In some embodiments, the semiconductor layer 505 has a band gap greater than a band gap of the semiconductor layer 503. In some embodiments, the semiconductor layer 503 may include a compound Al_{y}Ga_{(1-y)}N and the semiconductor layer 505 may include a compound AlₓGa₍₁₋ₓ₎N, in which 0<y<x<1. In some embodiments, the semiconductor layer 503 is used as a channel layer. In some embodiments, the semiconductor layer 503 is formed on a buffer layer (not shown). In some embodiments, the semiconductor layer 505 is used as a barrier layer. In some embodiments, because the band gap of the semiconductor layer 505 is greater than the band gap of the semiconductor layer 503, two dimensional electron gas (2DEG) is formed in the semiconductor layer 503 close to an interface between the semiconductor layer 503 and the semiconductor layer 505.

The contacts 504, 510, 522 are formed on the semiconductor layer 505. The contact 510 is between the contact 504 and the contact 522. The contacts 504, 510, 522 may include, for example, but is not limited to, a metal, such as Al, Ti, the like, or a combination thereof. The contacts 504, 510, 522 may include, for example, but is not limited to, a metal compound. The contacts 504, 510, 522 may include, for example, but is not limited to, titanium nitride (TiN). In some embodiments, the contacts 504, 510, 522 may include a capping metal, such as Ni, Au, Ti, TiN, the like, or a combination thereof. In some embodiments, the contacts 504, 510, 522 may be ohmic contact.

The gate structures 506, 526 are formed on the semiconductor layer 505. The gate structure 506 is formed between the contact 504 and the contact 510. The gate structure 526 is formed between the contact 510 and the contact 522. The gate structure 506 includes a doped semiconductor element 506A and a gate contact 506B. The gate structure 526 includes a doped semiconductor element 526A and a gate contact 526B. The doped semiconductor element 506A and/or the doped semiconductor element 526A may include, for example, but is not limited to, a group III-V semiconductor material. In some embodiments, the doped semiconductor element 506A and/or the doped semiconductor element 526A may include, for example, but is not limited to, a nitride semiconductor material. In some embodiments, the doped semiconductor element 506A and/or the doped semiconductor element 526A may include, for example, but is not limited to, a group III nitride material. In some embodiments, the doped semiconductor element 506A and/or the doped semiconductor element 526A may include, for example, but is not limited to, a p-type semiconductor material. In some embodiments, the doped semiconductor element 506A and/or the doped semiconductor element 526A may include, for example, but is not limited to, p-type GaN. The gate contact 506B and/or the gate contact 526B may include, for example, but not limited to, a metal such as Ni, Pt, Au, the like, or a combination thereof. In some embodiments, the gate contact 506B and/or the gate contact 526B may be Schottky contact.

In some embodiments, a shortest distance d2 between the gate structure 506 and the contact 510 may be smaller than a shortest distance d1 between the gate structure 506 and the contact 504. In some embodiments, a shortest distance d3 between the gate structure 526 and the contact 510 is greater than a shortest distance d4 between the gate structure 526 and the contact 522. In some embodiments, a shortest distance d2 between the gate structure 506 and the contact 510 is smaller than a shortest distance d3 between the gate structure 526 and the contact 510. The design of the distances d1, d2, d3 and/or d4 may improve the performance of the semiconductor device 5. For example, the distances d1, d2, d3 and/or d4 may be designed in accordance with Table 1.

TABLE 1

| Vᵢₙ | d1/(d1 + | d3/(d3 + | d1/(d1 + d2 + | d3/(d1 + d2 + |
|---|---|---|---|---|
| (Volt) | d2) | d4) | d3 + d4) | d3 + d4) |
| <5 | 0.50-0.91 | 0.50-0.91 | 0.25-0.45 | 0.20-0.38 |
| 5-<10 | 0.67-0.91 | 0.67-0.91 | 0.33-0.45 | 0.27-0.38 |
| 10-<20 | 0.75-0.91 | 0.75-0.91 | 0.37-0.45 | 0.31-0.38 |
| 20-<50 | 0.77-0.95 | 0.77-0.95 | 0.38-0.48 | 0.32-0.40 |
| 50-<100 | 0.87-0.96 | 0.87-0.96 | 0.43-0.48 | 0.36-0.40 |
| 100-<150 | 0.89-0.97 | 0.89-0.97 | 0.45-0.49 | 0.37-0.41 |
| ≥150 | 0.91-0.98 | 0.91-0.98 | 0.45-0.49 | 0.34-0.41 |

The distances d1, d2, d3 and/or d4 may be designed in accordance with Table 2.

TABLE 2

| Vᵢₙ (Volt) | d1 (μm) | d2 (μm) | d3 (μm) | d4 (μm) |
|---|---|---|---|---|
| <5 | 0.1-1 | 0.1-0.3 | 0.1-1 | 0.1-0.3 |
| 5-<10 | 0.2-1 | 0.1-0.3 | 0.2-1 | 0.1-0.3 |
| 10-<20 | 0.3-1 | 0.1-0.3 | 0.3-1 | 0.1-0.3 |
| 20-<50 | 1-2 | 0.1-0.3 | 1-2 | 0.1-0.3 |
| 50-<100 | 2-2.5 | 0.1-0.3 | 2-2.5 | 0.1-0.3 |
| 100-<150 | 2.5-3.5 | 0.1-0.3 | 2.5-3.5 | 0.1-0.3 |
| ≥150 | 3-5 | 0.1-0.3 | 3-5 | 0.1-0.3 |

As shown in FIG. 9, the semiconductor device 5 further includes a conductive wire 512 on the contact 510. The conductive wire 512 may include, for example, but is not limited to, a metal such as Al, Cu, W, the like, or a combination thereof. The conductive wire 512 may be electrically connected to the contact 510. The conductive wire 512 may be electrically connected to the contact 510 through a conductive via (not shown). The conductive wire 512 may electrically connect the contact 510 to a switch node.

As shown in FIG. 9, the semiconductor device 5 further includes a conductive wire 523 on the contact 522. The conductive wire 523 has an upper surface 523a and a lower surface 523b. The conductive wire 523 may include, for example, but is not limited to, a metal such as Al, Cu, W, the like, or a combination thereof. The conductive wire 523 may be electrically connected to the contact 522. The conductive wire 523 may be electrically connected to the contact 522 through a conductive via (not shown). The conductive wire 523 may electrically connect the contact 522 to ground (GND). The lower surface 523b of the conductive wire 523 may be connected to the contact 522. The lower surface 523b of the conductive wire 523 may extend beyond the contact 522.

As shown in FIG. 9, the semiconductor device 5 further includes a conductive via 528. The conductive via 528 may include, for example, but is not limited to, a metal such as Al, Cu, W, the like, or a combination thereof. The conductive via 528 is connected to the conductive wire 523. The conductive via 528 may be connected to the lower surface 523b of the conductive wire 523. The conductive via 528 may connect the conductive wire 523 and the substrate 501. The conductive via 528 may extend from the conductive wire 523 to the substrate 501. The conductive via 528 may terminate within the substrate 501. The conductive via 528 may extend from the conductive wire 523 to the semiconductor layer 505. The conductive via 526 may extend through the semiconductor layer 505. The conductive via 526 may extend through the semiconductor layer 503. The contact 522 may be between the gate structure 526 and the conductive via 528. The conductive wire 523 may be between the contact 522 and the conductive via 528. The conductive wire 523 may connect the contact 522 and the conductive via 528. The lower surface 523b of the conductive wire 523 may be connected to the contact 522 and the conductive via 528.

As shown in FIG. 9, the semiconductor device 5 further includes a dielectric layer 530 on the semiconductor layer 505. The dielectric layer 530 may include, for example, but is not limited to, silicon oxide, silicon nitride, aluminum oxide, aluminum nitride, or a combination thereof. The dielectric layer 530 may cover at least a portion of the contact 504. The dielectric layer 530 may cover at least a portion of the contact 510. The dielectric layer 530 may cover at least a portion of the contact 522. The dielectric layer 530 may cover at least a portion of the gate structure 506. The dielectric layer 530 may cover at least a portion of the gate structure 526. The dielectric layer 530 may cover at least a portion of the conductive wire 512. The dielectric layer 530 may cover at least a portion of the conductive wire 523. The dielectric layer 530 may cover at least a portion of the conductive via 528. The dielectric layer 530 may cover at least a portion of a lateral surface of the contact 504. The dielectric layer 530 may cover at least a portion of a lateral surface of the contact 510. The dielectric layer 530 may cover at least a portion of a lateral surface of the contact 522. The dielectric layer 530 may cover at least a portion of a lateral surface of the gate structure 506. The dielectric layer 530 may cover at least a portion of a lateral surface of the gate structure 526. The dielectric layer 530 may cover at least a portion of a lateral surface of the conductive wire 512. The dielectric layer 530 may cover at least a portion of a lateral surface of the conductive wire 523. The dielectric layer 530 may cover at least a portion of a lateral surface of the conductive via 528. The dielectric layer 530 may embed the contact 504. The dielectric layer 530 may embed the contact 510. The dielectric layer 530 may embed the contact 522. The dielectric layer 530 may embed the gate structure 506. The dielectric layer 530 may embed the gate structure 526. The dielectric layer 530 may embed the conductive wire 512. The dielectric layer 530 may embed the conductive wire 523. The dielectric layer 530 may cover at least a portion of an upper surface of the contact 504. The dielectric layer 530 may cover a portion of the lower surface 523b of the conductive wire 523. The conductive via 528 may extend through a portion of the dielectric layer 530. A portion of the dielectric layer 530 may be between the contact 522 and the conductive via 528. A portion of the dielectric layer 530 between the contact 522 and the conductive via 528 may cover a portion of the semiconductor layer 505. The conductive wire 523 may cover a portion of the dielectric layer 530 between the contact 522 and the conductive via 528. A portion of the dielectric layer 530 may be between the semiconductor layer 505 and the conductive wire 523. A portion of the dielectric layer 530 may be surrounded by the semiconductor layer 505, the contact 522, the conductive wire 523 and the conductive via 528.

As shown in FIG. 8 and FIG. 9, the semiconductor device 5 includes a device region 50 and a device region 52. The device region 50 includes the contacts 504, 510 and the gate structure 506. The device region 52 includes the contacts 510, 522 and the gate structure 526. The device region 50 and the device region shares the contact 510. The contact 510 may be referred to as a common contact. In the device region 50, the contact 504 may function as a drain contact and the contact 510 (common contact) may function as a source contact to the drain contact 504. In the device region 52, the contact 522 may function as a source contact and the contact 510 (common contact) may function as a drain contact to the source contact 522. The common contact 510 may be electrically connected to a switch node. The drain contact 504 may be electrically connected to a voltage supply (Vᵢₙ). The source contact 522 may be electrically connected to ground (GND). The semiconductor device 5 may be represented by the half-bridge circuit 1 shown in FIG. 1. The device region 50 may be represented by the transistor 10 shown in FIG. 1. The device region 50 may be referred to as a high-side device region or a high-side transistor. The device region 52 may be represented by the transistor 12 shown in FIG. 1. The device region 52 may be referred to as a low-side device region or a low-side transistor. In some embodiments, the source contact 510 of the device region 50 and the substrate 501 may be at different potentials and therefore the body effect may occur in the device region 50. To mitigate the body effect, the thickness of the semiconductor layer 503 may be increased.

Compared to the semiconductor device 3 shown in FIG. 3 and FIG. 4, in the semiconductor device 5 shown in FIG. 8 and FIG. 9, the device region 50 (high-side transistor) and the device region 52 (low-side transistor) are formed on a single substrate 501. The device region 50 and the device region 52 shares a common contact 510. In a direction substantially parallel to the direction connecting a source contact and a drain contact, the conductive wire 512 connecting the common contact 510 shared by the device region 50 and the device region 52 has a shorter length compared to the conductive wire 34 of the semiconductor device 3. As a result, parasitic resistance and parasitic inductance can be reduced. The issues of voltage spike or surge can be alleviated. The performance of the semiconductor device can thus be improved. In addition, the common contact 510 allows the size of the semiconductor device to be decreased and reduces cost. Another advantage of the semiconductor device 5 is relatively simple manufacture.

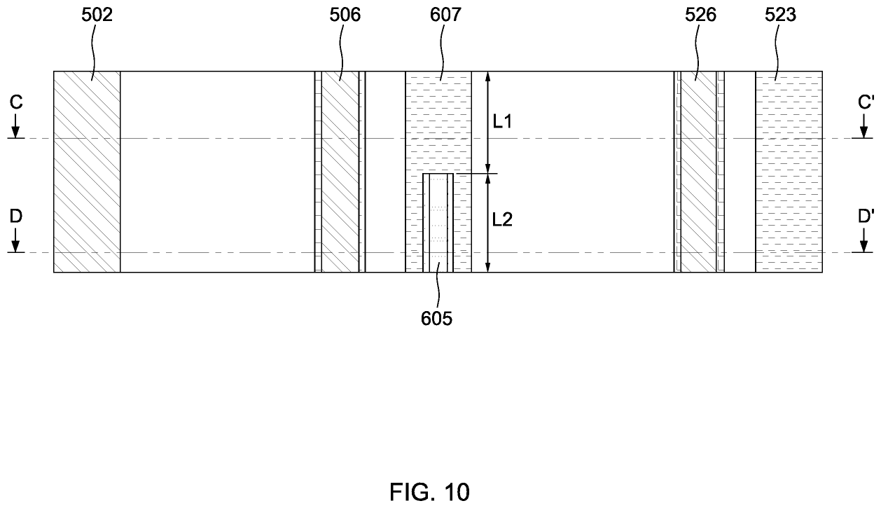

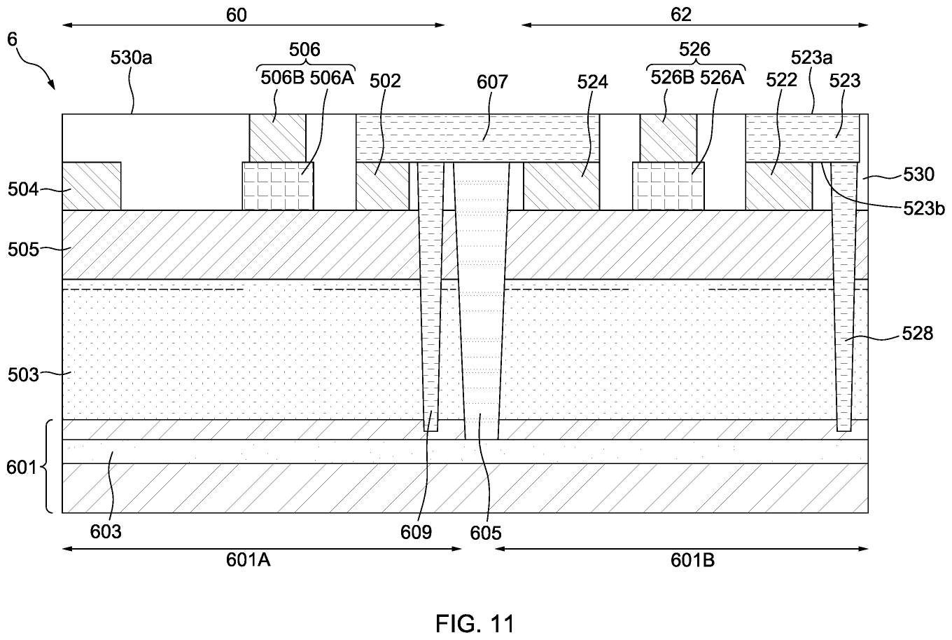

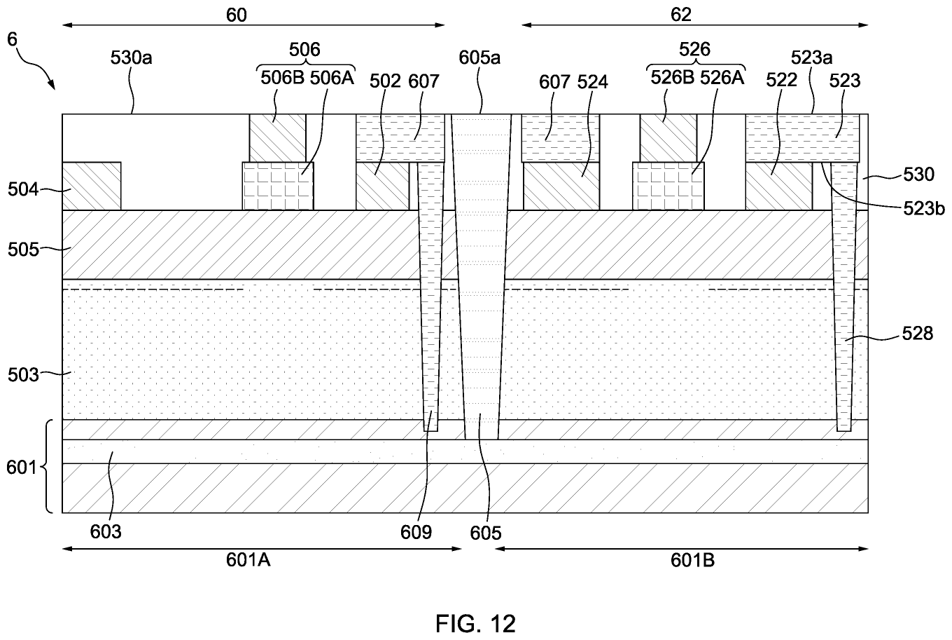

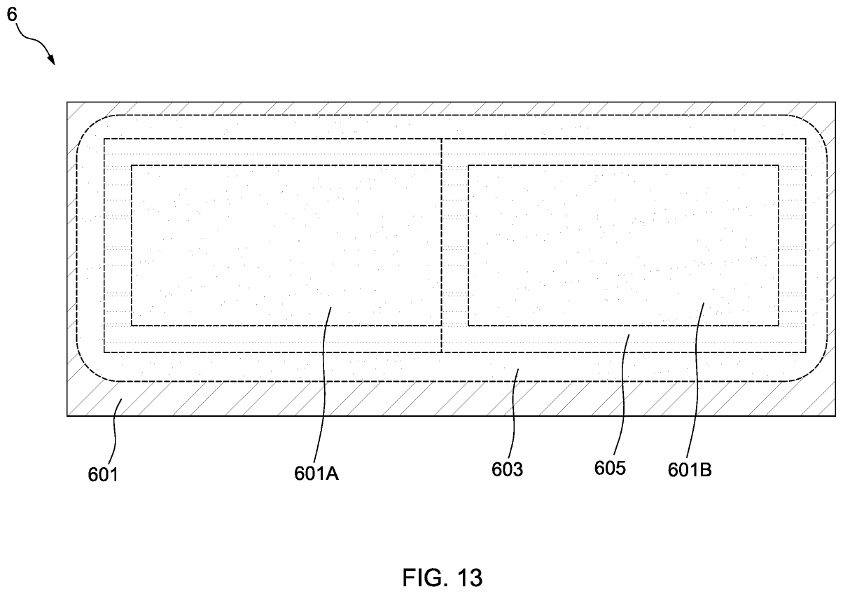

FIG. 10 illustrates a top view of a portion of a semiconductor device in accordance with some embodiments of the present disclosure. FIG. 10 shows an alternative layout to that shown in FIG. 8. FIG. 11 illustrates a cross-sectional view of a portion of a semiconductor device 6 taken along line C-C′ shown in FIG. 10 in accordance with some embodiments of the present disclosure. In some embodiments, FIG. 11 may illustrate a cross-sectional view of a portion of the semiconductor device 4A taken along line X-X′ shown in FIG. 5. In some embodiments, FIG. 11 may illustrate a cross-sectional view of a portion of the semiconductor device 4B taken along line Y-Y′ shown in FIG. 6. In some embodiments, FIG. 11 may illustrate a cross-sectional view of a portion of the semiconductor device 4C taken along line Z-Z′ shown in FIG. 7. FIG. 12 illustrates a cross-sectional view of a portion of the semiconductor device 6 taken long line D-D′ shown in FIG. 10 in accordance with some embodiments of the present disclosure. FIG. 13 illustrates a bottom view of a portion of the semiconductor device 6 shown in FIG. 11 and FIG. 12 in accordance with some embodiments of the present disclosure. As shown in FIG. 11 and FIG. 12, the semiconductor device 6 includes a substrate 601, a semiconductor layer 503, a semiconductor layer 505, contacts 502, 504, 522, 524 and gate structures 506, 526. The semiconductor layer 503 is formed on the substrate 601. The semiconductor layer 505 is formed on the semiconductor layer 503. The contacts 502, 504, 522, 524 and the gate structures 506, 526 are formed on the semiconductor layer 505.

As shown in FIG. 12 and FIG. 13, the substrate 601 includes a region 601A and a region 601B. The material of the substrate 601 may be identical or similar to the substrate 501. The substrate 601 includes an insulating layer 603. The insulating layer 603 may extend from the region 601A to the region 601B of the substrate 601. The insulating layer 603 may be buried in the substrate 601. The insulating layer 603 may be a buried insulating layer. In some embodiments, the insulating layer 603 may be a buried oxide layer. In some embodiments, the insulating layer 603 may include, but is not limited to, silicon oxide (SiOₓ).

As shown in FIG. 11 and FIG. 12, the semiconductor layer 503 is formed on the region 601A and the region 601B of the substrate 601. The semiconductor layer 505 is formed on the region 601A and the region 601B of the substrate 601. The contacts 502, 504 and the gate structure 506 are formed on the region 601A of the substrate 601. The gate structure 506 is formed between the contact 502 and the contact 504. The contacts 522, 524 and the gate structure 526 are formed on the region 601B of the substrate 601. The gate structure 526 is formed between the contact 522 and the contact 524. The contact 502 may be formed between the contact 504 and the contact 524. The contact 524 may be formed between the contact 522 and the contact 502.

As shown in FIG. 11 and FIG. 12, the semiconductor device 6 further includes an isolation structure 605 between the region 601A and the region 601B of the substrate 601. The isolation structure 605 may be a deep trench isolation (DTI) structure. The isolation structure 605 may include, for example, but is not limited to, silicon oxide, silicon nitride, aluminum oxide, aluminum nitride, or other suitable insulating material, or a combination thereof. The isolation structure 605 may extend through the semiconductor layer 505. The isolation structure 605 may extend through the semiconductor layer 503. The isolation structure 605 may extend to the insulating layer 603 of the substrate 601. The isolation structure 605 may contact the insulating layer 603 of the substrate 601. The isolation structure 605 may contact the insulating layer 603 buried in the substrate 601. The isolation structure 605 may isolate the semiconductor layer 503 on the region 601A of the substrate 601 from the semiconductor layer 503 on the region 601B of the substrate 601. The isolation structure 605 may isolate the semiconductor layer 505 on the region 601A of the substrate 601 from the semiconductor layer 505 on the region 601B of the substrate 601. Referring to the bottom view of FIG. 13, in some embodiments, the isolation structure 605 may surround the region 601A of the substrate 601. In some embodiments, the isolation structure 605 may surround the region 601B of the substrate 601. In some embodiments, the isolation structure 605 may surround the region 601A and the region 601B of the substrate 601. In some embodiments, a projection of the isolation structure 605 perpendicular to an upper surface 601a of the substrate 601 is located within the insulating layer 603 of the substrate 601.

As shown in FIG. 11 and FIG. 12, the semiconductor device 6 further includes a conductive wire 607 on the contacts 502, 524. The conductive wire 607 may include, for example, but is not limited to, a metal such as Al, Cu, W, the like, or a combination thereof. The conductive wire 607 may be electrically connected to the contacts 502, 524. The conductive wire 607 may be electrically connected to the contacts 502, 524 through a respective conductive via (not shown). The conductive wire 607 may electrically connect the contacts 502, 524 to a switch node. The conductive wire 607 may extend over the isolation structure 605. The conductive wire 607 may extend across the isolation structure 605. A projection of the conductive wire 607 perpendicular to an upper surface 601a of the substrate 601 may overlap the isolation structure 605. The conductive wire 607 may cover an upper surface of the isolation structure 605. The isolation structure 605 may be connected to a lower surface of the conductive wire 607. The isolation structure 605 may extend from the conductive wire 607 to the semiconductor layer 505. Referring to FIG. 12, the isolation structure 605 may be disposed between a portion of the conductive wire 607 and another portion of the conductive wire 607 according to some embodiments of the present disclosure.

Referring to the top view shown in FIG. 10, in some embodiments, a portion of the conductive wire 607 covers the isolation structure 605 and has a length L1. Another portion of the conductive wire 607 may expose the isolation structure 605 and has a length L2. In some embodiments, the length L1 is greater than the length L2. The length L2 may be zero. When the length L2 is zero, the top view of the semiconductor device 6 may be similar to the top view shown in FIG. 8.

Referring to FIG. 11 and FIG. 12, the semiconductor device 6 may further include a conductive via 609 connected to the conductive wire 607. The conductive via 609 may include, for example, but is not limited to, a metal such as Al, Cu, W, the like, or a combination thereof. The material of the conductive via 609 may be the same as the material of the conductive wire 607. The conductive via 609 may connect the conductive wire 607 to the region 601A of the substrate 601. The conductive via 609 may connect the conductive wire 607 to a substrate layer (such as an SOI layer) on the insulating layer 603 of the substrate 601. The conductive via 609 may extend from the conductive wire 607 to the semiconductor layer 505. The conductive via 609 may extend through the semiconductor layer 505. The conductive via 609 may extend through the semiconductor layer 503. The conductive via 609 may extend to the region 601A of the substrate 601. The conductive via 609 may extend to a portion of the substrate 601 arranged on the insulating layer 603 (such as an SOI layer). The conductive via 609 may terminate before reaching the insulating layer 603 of the substrate 601. The conductive via 609 may terminate within the portion of the substrate 601 arranged on the insulating layer 603 (such as an SOI layer). The conductive via 609 may be disposed between the contact 502 and the isolation structure 605.

The semiconductor device 6 may further include a conductive wire 523 on the contact 522. The arrangement of the conductive wire 523 may be identical or similar to that shown in FIG. 9. The semiconductor device 6 may further include a conductive via 528 connected to the conductive wire 523. The arrangement of the conductive via 528 may be identical or similar to that shown in FIG. 9. The conductive via 528 connects the conductive wire 523 to the region 601B of the substrate 601. The conductive via 528 may connect the conductive wire 523 to a portion of the substrate 601 arranged on the insulating layer 603 (such as an SOI layer). The conductive via 528 may terminate before reaching the insulating layer 603 of the substrate 601. The conductive via 528 may terminate within the portion of the substrate 601 arranged on the insulating layer 603 (such as an SOI layer).

As shown in FIG. 11 and FIG. 12, the semiconductor device 6 may further include a dielectric layer 530 on the semiconductor layer 505. The dielectric layer 530 may cover at least a portion of the contact 502. The dielectric layer 530 may cover at least a portion of the contact 504. The dielectric layer 530 may cover at least a portion of the contact 522. The dielectric layer 530 may cover at least a portion of the contact 524. The dielectric layer 530 may cover at least a portion of the gate structure 506. The dielectric layer 530 may cover at least a portion of the gate structure 526. The dielectric layer 530 may cover at least a portion of the isolation structure 605. The dielectric layer 530 may cover at least a portion of the conductive wire 607. The dielectric layer 530 may cover at least a portion of the conductive wire 523. The dielectric layer 530 may cover at least a portion of the conductive via 528. The dielectric layer 530 may cover at least a portion of the conductive via 609. The dielectric layer 530 may cover at least a portion of a lateral surface of the contact 502. The dielectric layer 530 may cover at least a portion of a lateral surface of the contact 504. The dielectric layer 530 may cover at least a portion of a lateral surface of the contact 522. The dielectric layer 530 may cover at least a portion of a lateral surface of the contact 524. The dielectric layer 530 may cover at least a portion of a lateral surface of the gate structure 506. The dielectric layer 530 may cover at least a portion of a lateral surface of the gate structure 526. The dielectric layer 530 may cover at least a portion of a lateral surface of the isolation structure 605. The dielectric layer 530 may cover at least a portion of a lateral surface of the conductive wire 607. The dielectric layer 530 may cover at least a portion of a lateral surface of the conductive wire 523. The dielectric layer 530 may cover at least a portion of a lateral surface of the conductive via 528. The dielectric layer 530 may cover at least a portion of a lateral surface of the conductive via 609. The dielectric layer 530 may embed the contact 502. The dielectric layer 530 may embed the contact 504. The dielectric layer 530 may embed the contact 522. The dielectric layer 530 may embed the contact 524. The dielectric layer 530 may embed the gate structure 506. The dielectric layer 530 may embed the gate structure 526. The dielectric layer 530 may embed the conductive wire 607. The dielectric layer 530 may embed the conductive wire 523. The dielectric layer 530 may cover a portion of an upper surface of the contact 502. The dielectric layer 530 may cover at least a portion of an upper surface of the contact 504. The dielectric layer 530 may cover a portion of an upper surface of the contact 522. The dielectric layer 530 may cover a portion of an upper surface of the contact 524. The dielectric layer 530 may cover a portion of the lower surface 523b of the conductive wire 523. The dielectric layer 530 may cover a portion of a lower surface of the conductive wire 607. The isolation structure 605 may extend through a portion of the dielectric layer 530. The conductive via 528 may extend through a portion of the dielectric layer 530. The conductive via 609 may extend through a portion of the dielectric layer 530. A portion of the dielectric layer 530 may be between the contact 522 and the conductive via 528. A portion of the dielectric layer 530 between the contact 522 and the conductive via 528 may cover a portion of the semiconductor layer 505. The conductive wire 523 may cover a portion of the dielectric layer 530 between the contact 522 and the conductive via 528. A portion of the dielectric layer 530 between the contact 502 and the conductive via 609 may cover a portion of the semiconductor layer 505. The conductive wire 607 may cover a portion of the dielectric layer 530 between the contact 502 and the conductive via 609. A portion of the dielectric layer 530 may be between the semiconductor layer 505 and the conductive wire 523. A portion of the dielectric layer 530 may be surrounded by the semiconductor layer 505, the contact 522, the conductive wire 523 and the conductive via 528. A portion of the dielectric layer 530 may be between the contact 502 and the conductive via 609. A portion of the dielectric layer 530 may be between the conductive via 609 and the isolation structure 605. A portion of the dielectric layer 530 may be between the isolation structure 605 and the contact 524. A portion of the dielectric layer 530 may be between the semiconductor layer 505 and the conductive wire 607. Referring to FIG. 12, a portion of an upper surface 605a of the isolation structure 605 may be exposed from dielectric layer 530. In some embodiments, a portion of an upper surface 605a of the isolation structure 605 may be coplanar with an upper surface 530a of the dielectric layer 530.

As shown in FIG. 11 and FIG. 12, the semiconductor device 6 includes a device region 60 and a device region 62. The device region 60 includes the contacts 502, 504 and the gate structure 506. The device region 62 includes the contacts 522, 524 and the gate structure 526. The isolation structure 605 in combination with the insulating layer 603 may isolate the device region 60 and the device region 62 from each other. In the device region 60, the contact 504 may function as a drain contact, and the contact 502 may function as a source contact to the drain contact 504. In the device region 62, the contact 522 may function as a source contact and the contact 524 may function as a drain contact to the drain contact 524. The source contact 502 and the drain contact 524 may be electrically connected to a switch node. The drain contact 504 may be electrically connected to a voltage supply (Vᵢₙ). The source contact 522 may be electrically connected to ground (GND). The semiconductor device 6 may be represented by the half-bridge circuit 1 shown in FIG. 1. The device region 60 may be represented by the transistor 10 shown in FIG. 1. The device region 60 may be referred to as a high-side device region or a high-side transistor. The device region 62 may be represented by the transistor 12 shown in FIG. 1. The device region 62 may be referred to as a low-side device region or a low-side transistor.

Compared to the semiconductor device 3 shown in FIG. 3 and FIG. 4, in the semiconductor device 6 shown in FIG. 10 to FIG. 13, the device region 60 (high-side transistor) and the device region 62 (low-side transistor) are formed on a single substrate 601. Therefore, in a direction substantially parallel to the direction connecting a source contact and a drain contact, the conductive wire 607 of the semiconductor device 6 may have a shorter length compared to the conductive wire 34 of the semiconductor device 3. As a result, parasitic resistance and parasitic inductance can be reduced. The issues of voltage spike or surge can be alleviated. The performance of the semiconductor device can thus be improved. In addition, the isolation structure 605 allows to integrate a high-side transistor and a low-side transistor on a single substrate of relatively small area and facilitate miniaturization of the semiconductor device or chip. The isolation structure 605 allows to isolate the device region 60 from the device region 62 of the semiconductor device 6 and reduces the crosstalk between the device region 60 and the device region 62. In some embodiments, the conductive wire 607 and the conductive via 609 electrically connect the source contact 502 to the region 601A of the substrate 601. Therefore, the source contact 502 and the region 601A of the substrate are at the same potential and the body effect can be alleviated or avoided in the device region 60 of the semiconductor device 6.

The performance of the semiconductor device can thus be further improved.

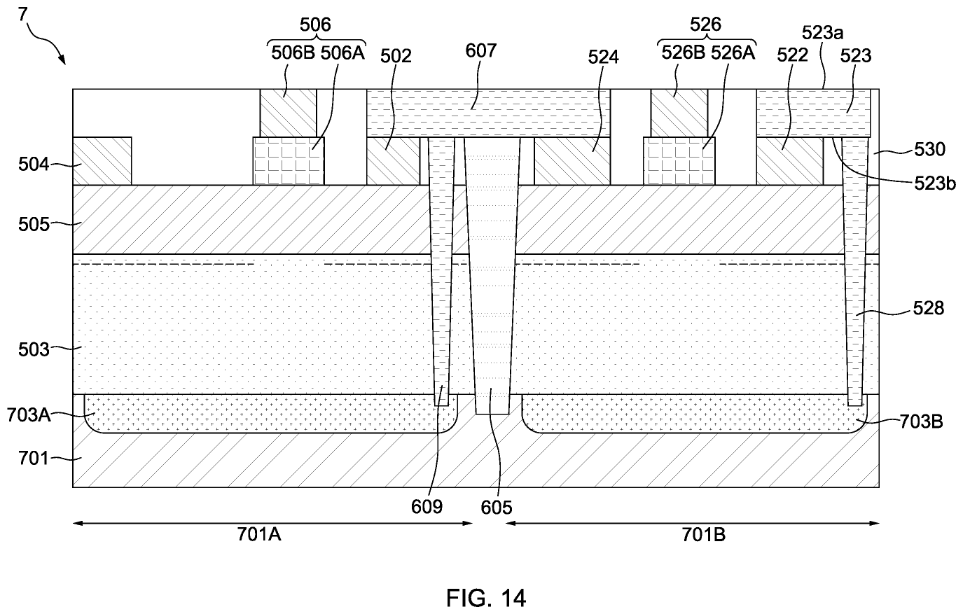

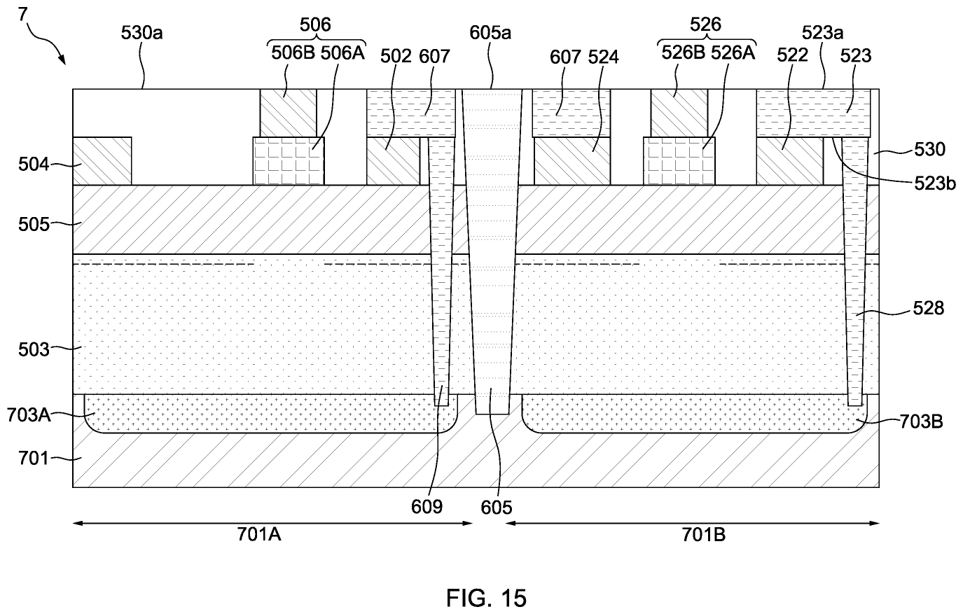

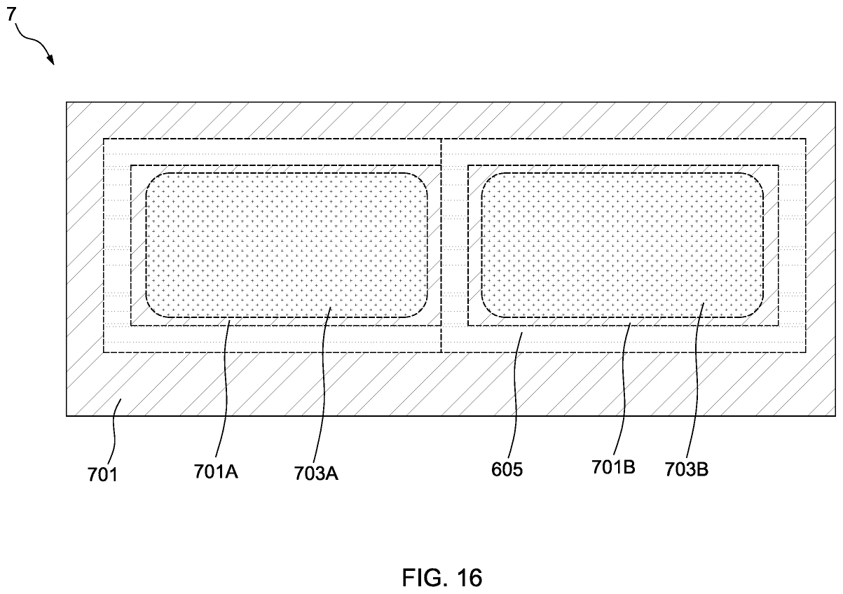

FIG. 14 illustrates a cross-sectional view of a portion of a semiconductor device 7 taken along line C-C′ shown in FIG. 10 in accordance with some embodiments of the present disclosure. FIG. 15 illustrates a cross-sectional view of a portion of a semiconductor device taken along line D-D′ shown in FIG. 10 in accordance with some embodiments of the present disclosure. FIG. 16 illustrates a bottom view of a portion of the semiconductor device 7 shown in FIG. 14 and FIG. 15 in accordance with some embodiments of the present disclosure. The semiconductor device 7 is similar to the semiconductor device 6 except for at least the following differences. The semiconductor device 7 includes a substrate 701 having a region 701A and a region 701B. The material of the substrate 701 may be identical or similar to the substrate 501. The semiconductor device 7 further includes an opposite-doped region 703A and an opposite-doped region 703B. In the present disclosure, the opposite-doped region refers to a region in a substrate having doping polarity opposite to the background doping polarity of the substrate. The opposite-doped region 703A is formed in the region 701A of the substrate 701. The opposite-doped region 703B is formed in the region 701B of the substrate 701. The opposite-doped region 703A is doped with opposite polarity to the substrate 701. For example, the opposite-doped region 703A may be a p-type doped region and the substrate 701 may be an n-type substrate.

Alternatively, the opposite-doped region 703A may be an n-type doped region and the substrate 701 may be a p-type substrate. The opposite-doped region 703B is doped with opposite polarity to the substrate 701. For example, the opposite-doped region 703B may be a p-type doped region and the substrate 701 may be an n-type substrate. Alternatively, the opposite-doped region 703B may be an n-type doped region and the substrate 701 may be a p-type substrate. A lower surface of the opposite-doped region 703A may be may be coplanar with a lower surface of the opposite-doped region 703B. A lower surface of the opposite-doped region 703A may be lower than a lower surface of the opposite-doped region 703B. A lower surface of the opposite-doped region 703A may be higher than a lower surface of the opposite-doped region 703B. In some embodiments where the substrate 701 is a p-type substrate, the substrate 701 is electrically connected to ground (GND), for example, through a conductive paste, in a conductive pin and/or a conductive line in a packaging structure, to reduce noise from the substrate 701. In some embodiments where the substrate 701 is a n-type substrate, the substrate 701 is electrically connected to a voltage supply (Vᵢₙ), for example, through a conductive paste, a conductive pin and/or a conductive line in a packaging structure, to reduce noise from the substrate 701.

As shown in FIG. 14 and FIG. 15, the semiconductor layer 503 is formed on the region 701A and the region 701B of the substrate 701. The semiconductor layer 505 is formed on the region 701A and the region 701B of the substrate 601. The contacts 502, 504 and the gate structure 506 are formed on the region 701A of the substrate 701. The contacts 522, 524 and the gate structure 526 are formed on the region 701B of the substrate 701. The contacts 502, 504 and the gate structure 506 may be formed on the opposite-doped region 701A. The contacts 522, 524 and the gate structure 526 may be formed on the opposite-doped region 701B.

Referring to FIG. 14 and FIG. 15, the isolation structure 605 is disposed between the region 701A and the region 701B of the substrate 601. The isolation structure 605 is disposed between the opposite-doped region 703A and the opposite-doped region 703B. The isolation structure 605 extends to the substrate 701. In some embodiments, a lower surface of the isolation structure 605 may be higher than a lower surface of the opposite-doped region 703A. A lower surface of the isolation structure 605 may be higher than a lower surface of the opposite-doped region 703B. A lower surface of the isolation structure 605 may be lower than a lower surface of the opposite-doped region 703A. A lower surface of the isolation structure 605 may be lower than a lower surface of the opposite-doped region 703B. A lower surface of the isolation structure 605 may be between a lower surface of the opposite-doped region 703A and a lower surface of the opposite-doped region 703B. A lower surface of the opposite-doped region 703A may be between a lower surface of the isolation structure 605 and a lower surface of the opposite-doped region 703B. A lower surface of the opposite-doped region 703B may be between a lower surface of the isolation structure 605 and a lower surface of the opposite-doped region 703A. The isolation structure 605 isolates the semiconductor layer 503 on the region 701A of the substrate 701 from the semiconductor layer 503 on the region 701B of the substrate 701. The isolation structure 605 isolates the semiconductor layer 505 on the region 701A of the substrate 701 from the semiconductor layer 505 on the region 701B of the substrate 701. Referring to FIG. 16, in some embodiments, the isolation structure 605 may surround the opposite-doped region 703A. In some embodiments, the isolation structure 605 may surround the opposite-doped region 703B. In some embodiments, the isolation structure 605 may surround the opposite-doped region 703A and the opposite-doped region 703B.

Still referring to FIG. 14 and FIG. 15, the conductive via 609 connects the conductive wire 607 to the opposite-doped region 703A. The conductive via 609 extends from the conductive wire 607 to the opposite-doped region 703A. The conductive via 609 terminates within the opposite-doped region 703A. The conductive via 528 connects the conductive wire 523 to the opposite-doped region 703B. The conductive via 528 extends from the conductive wire 523 to the opposite-doped region 703B. The conductive via 528 terminates within the opposite-doped region 703B.

Similar to the semiconductor device 6, a high-side transistor and a low-side transistor are integrated on a single substrate 701 in the semiconductor device 7. Therefore, in a direction substantially parallel to the direction connecting a source contact and a drain contact, the conductive wire 607 of the semiconductor device 7 may have a shorter length compared to the conductive wire 34 of the semiconductor device 3. As a result, parasitic resistance and parasitic inductance can be reduced. The issues of voltage spike or surge can be alleviated. The performance of the semiconductor device can thus be improved. In addition, the isolation structure 605 allows to integrate a high-side transistor and a low-side transistor on a single substrate of relatively small area and facilitate miniaturization of the semiconductor device or chip. The isolation structure 605 can also reduce the crosstalk between the high-side transistor and the low-side transistor. In some embodiments, the conductive wire 607 and the conductive via 609 electrically connect the source contact 502 to the opposite-doped region 703A. Therefore, the body effect can be alleviated or avoided. The performance of the semiconductor device can thus be further improved. Another advantage of the semiconductor device 7 is relatively low cost of manufacture.

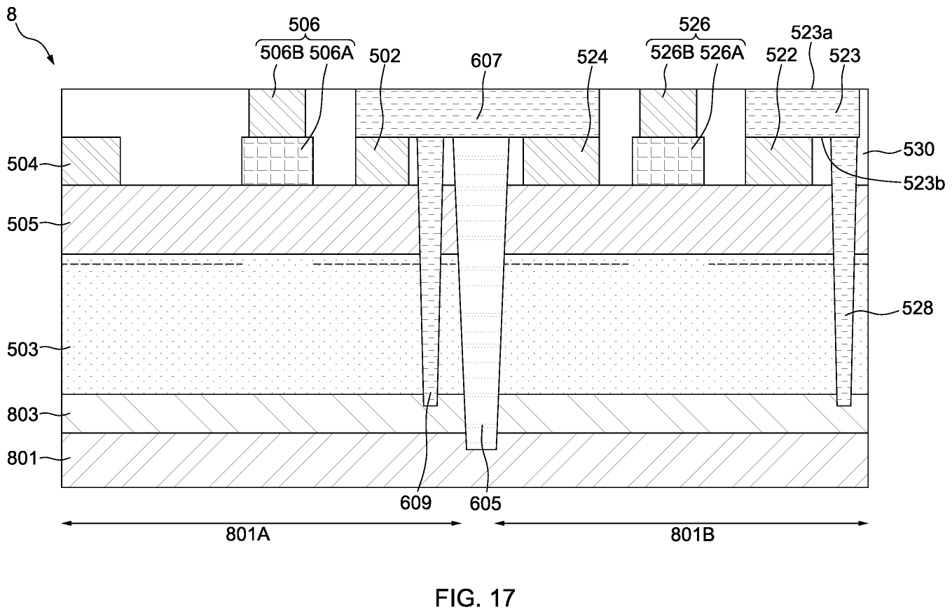

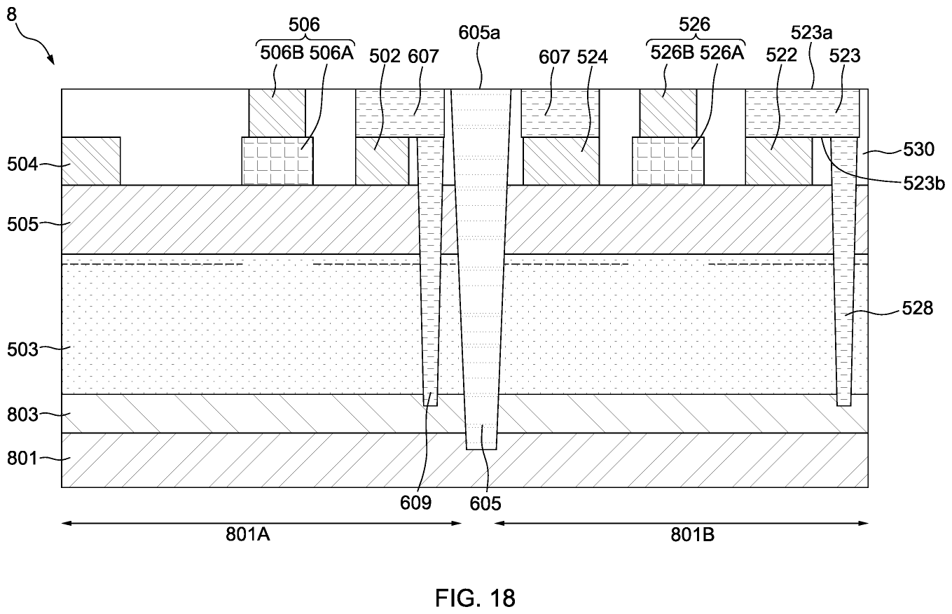

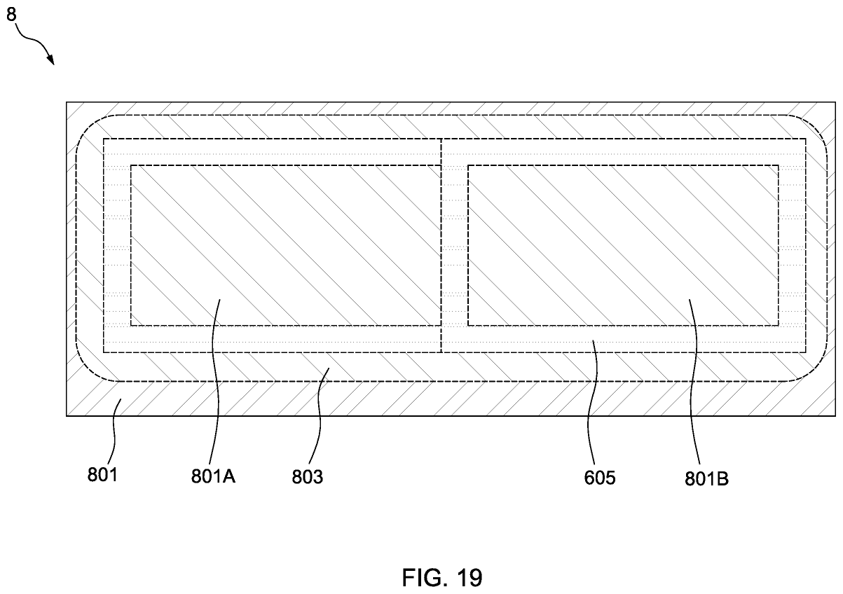

FIG. 17 illustrates a cross-sectional view of a portion of a semiconductor device 8 taken along line C-C′ shown in FIG. 10 in accordance with some embodiments of the present disclosure. FIG. 18 illustrates a cross-sectional view of a portion of the semiconductor device 8 taken along line D-D′ shown in FIG. 10 in accordance with some embodiments of the present disclosure. FIG. 19 illustrates a bottom view of a portion of the semiconductor device 8 shown in FIG. 17 and FIG. 18 in accordance with some embodiments of the present disclosure. The semiconductor device 8 is similar to the semiconductor device 6 except for at least the following differences. The semiconductor device 8 includes a substrate 801 having a region 801A and a region 801B. The material of the substrate 801 may be identical or similar to the substrate 501. The semiconductor device 8 further includes a doped semiconductor layer 803. The semiconductor layer 803 may include, for example, but is not limited to, a silicon-based material such as silicon. The doped semiconductor layer 803 is formed on the region 801A and the region 801B of the substrate 801. The substrate 801 may include the doped semiconductor layer 803 as an extrinsic doping layer. The doped semiconductor layer 803 is doped with opposite polarity to the substrate 801. For example, the doped semiconductor layer 803 may be a p-type semiconductor layer and the substrate 801 may be an n-type substrate. Alternatively, the doped semiconductor layer 803 may be an n-type semiconductor layer and the substrate 701 may be a p-type substrate. A p-n junction is formed between the doped semiconductor layer 803 and the substrate 801. In some embodiments where the substrate 801 is a p-type substrate, the substrate 801 may be electrically connected to ground (GND), for example, through a conductive paste, a conductive pin and/or a conductive line in a packaging structure, to reduce noise from the substrate 801. In some embodiments where the substrate 801 is a n-type substrate, the substrate 801 may be electrically connected to a voltage supply (Vᵢₙ), for example, through a conductive paste, a conductive pin and/or a conductive line in a packaging structure, to reduce noise from the substrate 801.

As shown in FIG. 17 and FIG. 18, the semiconductor layer 503 is formed on the doped semiconductor layer 803 on the region 801A and the region 801B of the substrate 801. The semiconductor layer 505 is formed on the semiconductor layer 503 on the region 801A and the region 801B of the substrate 801. The contacts 502, 504 and the gate structure 506 are formed on the region 801A of the substrate 801. The contacts 522, 524 and the gate structure 526 are formed on the region 801B of the substrate 801.

Referring to FIG. 17 and FIG. 18, the isolation structure 605 is disposed between the region 801A and the region 801B of the substrate 801. The isolation structure 605 extends through the doped semiconductor layer 803. The isolation structure 605 extends to the substrate 801. The isolation structure 605 terminates within the substrate 801. The isolation structure 605 isolates the doped semiconductor layer 803 on the region 801A of the substrate 801 from the doped semiconductor layer 803 on the region 801B of the substrate 801. The isolation structure 605 isolates the semiconductor layer 503 on the region 801A of the substrate 801 from the semiconductor layer 503 on the region 801B of the substrate 801. The isolation structure 605 isolates the semiconductor layer 505 on the region 801A of the substrate 801 from the semiconductor layer 505 on the region 801B of the substrate 801. Referring to FIG. 19, in some embodiments, the isolation structure 605 may surround the region 801A of the substrate 801. In some embodiments, the isolation structure 605 may surround the region 801B of the substrate 801. In some embodiments, the isolation structure 605 may surround the region 801A and the region 801B of the substrate 801. In some embodiments, the isolation structure 605 is disposed within the doped semiconductor layer 803 from a bottom view as shown in FIG. 19. In some embodiments, a projection of the isolation structure 605 perpendicular to an upper surface of the substrate 801 is located within the doped semiconductor layer 803.

Still referring to FIG. 17 and FIG. 18, the conductive via 609 connects the conductive wire 607 to the doped semiconductor layer 803 on the region 801A of the substrate 801. The conductive via 609 extends from the conductive wire 607 to the doped semiconductor layer 803 on the region 801A of the substrate 801. The conductive via 609 terminates within the doped semiconductor layer 803 on the region 801A of the substrate 801. The conductive via 528 connects the conductive wire 523 to the doped semiconductor layer 803 on the region 801B of the substrate 801. The conductive via 528 extends from the conductive wire 523 to the doped semiconductor layer 803 on the region 801B of the substrate 801. The conductive via 528 terminates within the doped semiconductor layer 803 on the region 801B of the substrate 801.

Similar to the semiconductor device 6, a high-side transistor and a low-side transistor are integrated on a single substrate 801 in the semiconductor device 8. Therefore, in a direction substantially parallel to the direction connecting a source contact and a drain contact, the conductive wire 607 of the semiconductor device 8 may have a shorter length compared to the conductive wire 34 of the semiconductor device 3. As a result, parasitic resistance and parasitic inductance can be reduced. The issues of voltage spike or surge can be alleviated. The performance of the semiconductor device can thus be improved. In addition, the isolation structure 605 allows to integrate a high-side transistor and a low-side transistor on a single substrate of relatively small area and facilitate miniaturization of the semiconductor device or chip. The isolation structure 605 can also reduce the crosstalk between the high-side transistor and the low-side transistor. In some embodiments, the conductive wire 607 and the conductive via 609 electrically connect the source contact 502 to the doped semiconductor layer 803 on the region 801A of the substrate 801. Therefore, the body effect can be alleviated or avoided. The performance of the semiconductor device can thus be further improved. Another advantage of the semiconductor device 8 is relatively simple manufacture.

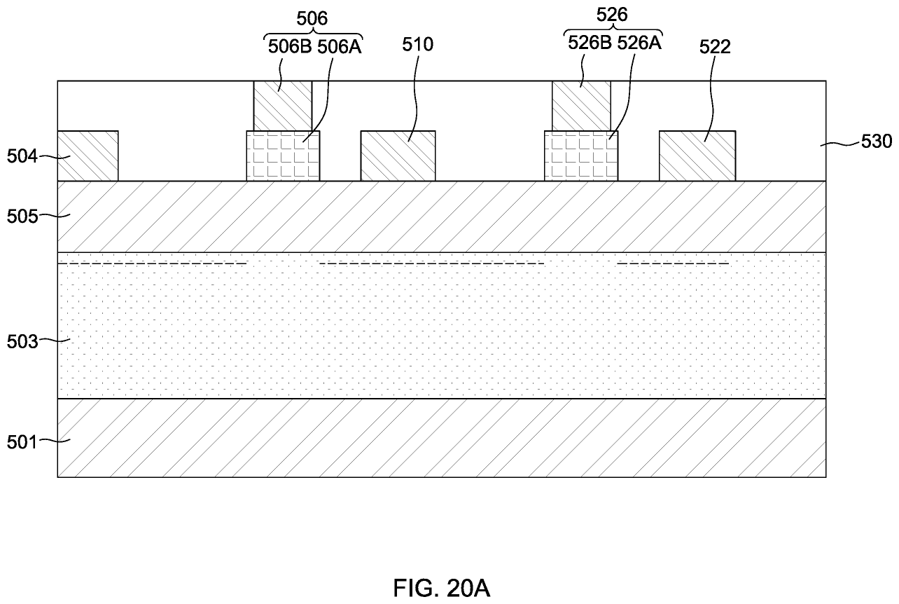

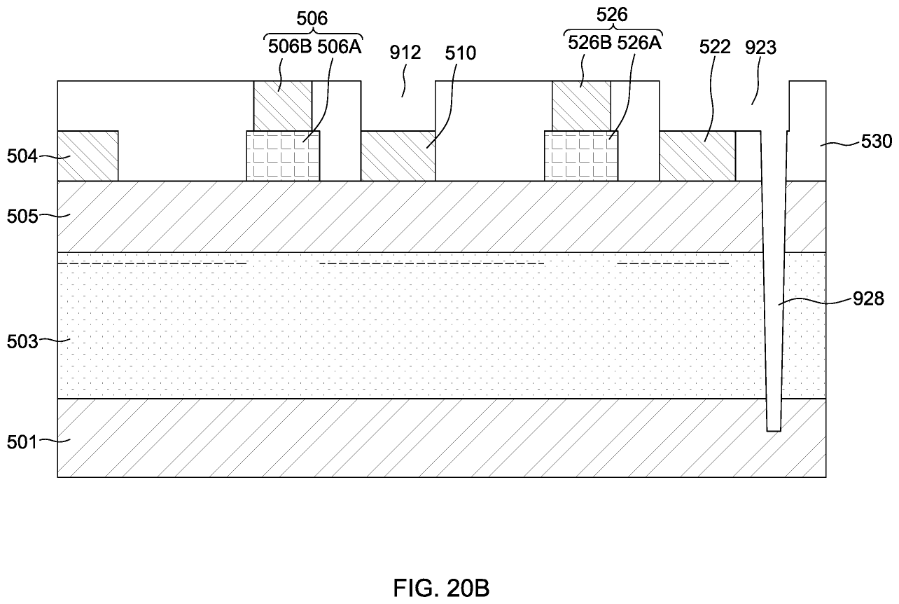

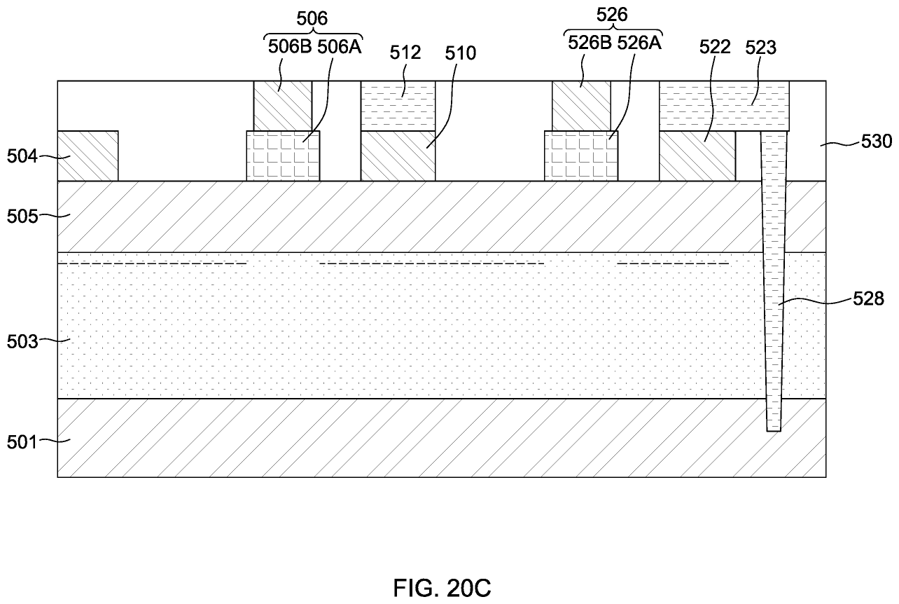

FIG. 20A, FIG. 20B, and FIG. 20C illustrate some operations to manufacture the semiconductor device 6 in accordance with some embodiments of the present disclosure. As shown in FIG. 20A, a substrate 501 is provided. A semiconductor layer 503 is formed on the substrate 501. In some embodiments, before the formation of the semiconductor layer 503, one or more buffer layers (not shown) may be formed on the substrate 501. The semiconductor layer 503 may be formed on the one or more buffer layers. The semiconductor layer 503 may be formed by chemical vapor deposition (CVD) and/or another suitable deposition operation. The semiconductor layer 505 is formed on the semiconductor layer 503. The semiconductor layer 505 may be formed by CVD and/or another suitable deposition operation. A gate structure 506 including a doped semiconductor element 506A and a gate contact 506B is formed on the semiconductor layer 505. The gate structure 506 may be formed by CVD, PVD, ALD and/or another suitable deposition operation. A gate structure 526 including a doped semiconductor element 526A and a gate contact 526B is formed on the semiconductor layer 505. The gate structure 526 may be formed by CVD, PVD, ALD and/or another suitable deposition operation. Contacts 504, 510, 522 are formed on the semiconductor layer 505. The contacts 504, 510, 522 may be formed by CVD, PVD, ALD and/or another suitable deposition operation. A dielectric layer 530 is formed on the semiconductor layer 505. The dielectric layer 530 may be formed by CVD, PVD, and/or another suitable deposition operation. In some embodiments, the dielectric layer 530 may include multiple layers. In some embodiments, the gate structure 506 and the gate structure 526 may be formed before the contacts 504, 510, 522 are formed. In some embodiments, the gate structure 506 and the gate structure 526 may be formed after the contacts 504, 510, 522 are formed. In some embodiments, the gate structure 506 and the gate structure 526 may be formed simultaneously. In some embodiments, the contacts 504, 510, 522 may be formed simultaneously. In some embodiments, after the gate structure 506 and the gate structure 526 are formed, a first sublayer of the dielectric layer 530 is formed to cover the gate structure 506, the gate structure 526 and the semiconductor layer 505. In some embodiments, a portion of the first sublayer of the dielectric layer 530 is removed to form openings and the contacts 504, 510, 522 are formed in the openings. A portion of the first sublayer of the dielectric layer 530 may be removed by etching. In some embodiments, after the contacts 504, 510, 522 are formed, a second sublayer of the dielectric layer 530 is formed to cover the contacts 504, 510, 522.

As shown in FIG. 20B, a trench 912 is formed on the contact 510 by removing a portion of the dielectric layer 530. The trench 912 may be formed by etching and/or another suitable removing operation. A trench 923 is formed on the contact 522 by removing a portion of the dielectric layer 530. The trench 923 may be formed by etching and/or another suitable removing operation. A via 928 is formed by removing a portion of the dielectric layer 530, a portion of the semiconductor layer 505, a portion of the semiconductor layer 503 and a portion of the substrate 501. The via 928 may be formed by etching and/or another suitable removing operation. The via 928 extends from the trench 923 to the substrate 501. In some embodiments, after the via 928 is formed, the trench 912 and the trench 923 are formed.

As shown in FIG. 20C, a conductive wire 512 is formed on the contact 510 by depositing a conductive material in the trench 912. The conductive wire 512 may be formed by CVD, PVD, ALD, and/or another suitable deposition operation. A conductive via 528 is formed by depositing a conductive material in the via 928. The conductive wire 528 may be formed by CVD, PVD, ALD, and/or another suitable deposition operation. A conductive wire 523 is formed by depositing a conductive material in the trench 923. The conductive wire 523 may be formed by CVD, PVD, ALD, and/or another suitable deposition operation. In some embodiments, the trench 912, the trench 923 and the via 928 may be simultaneously filled with a conductive material. In some embodiments, the conductive wire 512, the conductive wire 523 and the conductive via 528 may be formed in the same operation. In some embodiments, after deposition of a conductive material in the trench 912, the trench 923 and the via 928, a planarization operation is carried out to remove excess conductive material. The planarization operation may be chemical mechanical planarization (CMP). In some embodiments, an upper surface of the conductive wire 512 may be coplanar with an upper surface of the dielectric layer 530. In some embodiments, an upper surface of the conductive wire 523 may be coplanar with an upper surface of the dielectric layer 530.

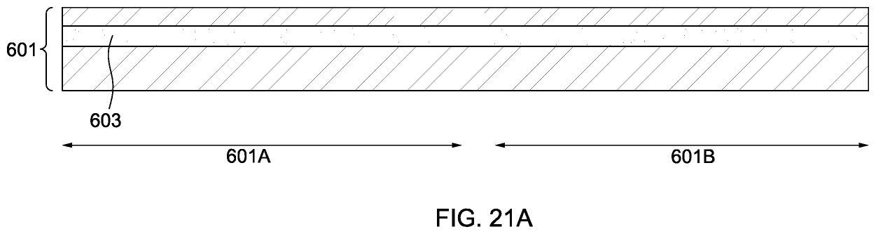

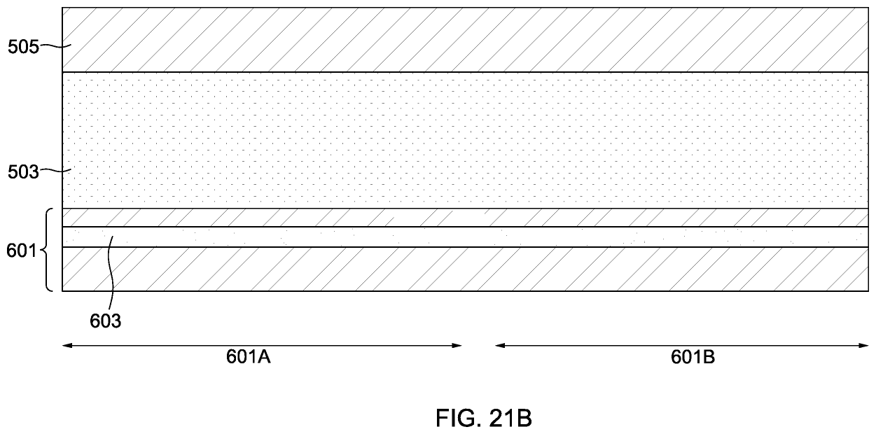

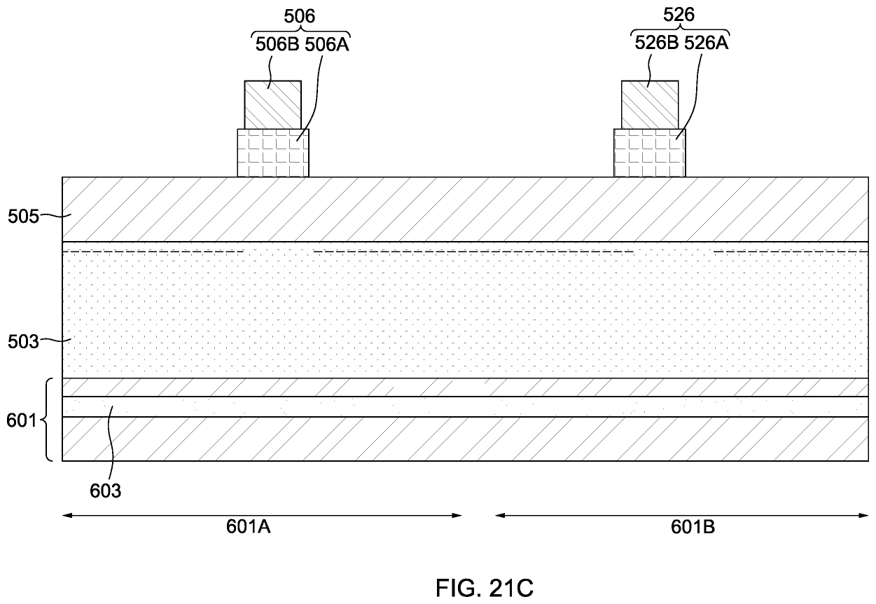

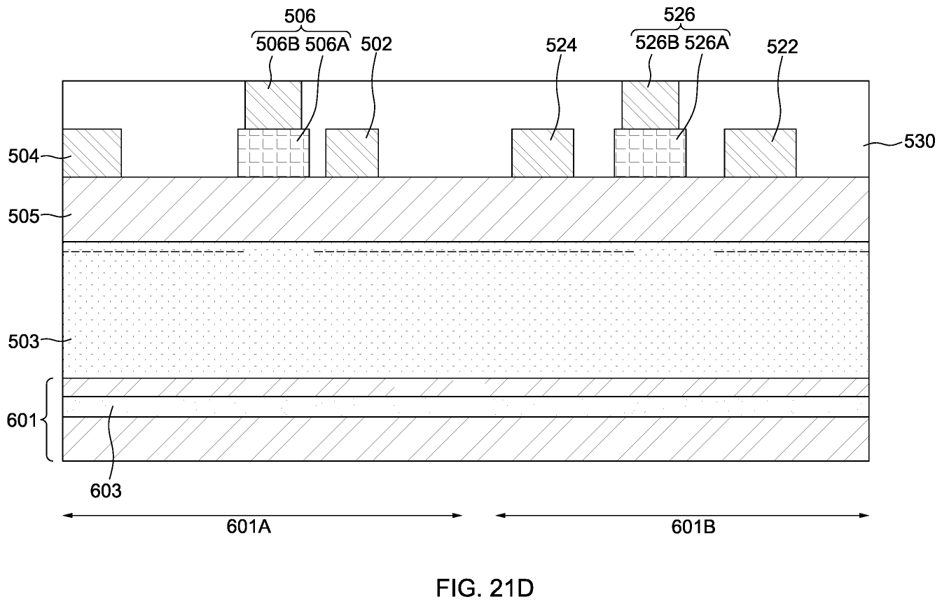

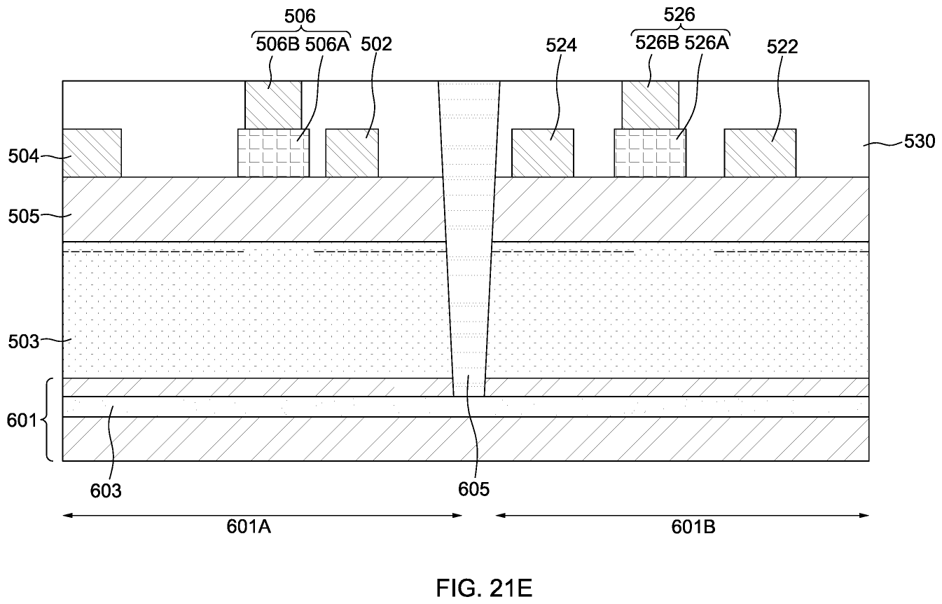

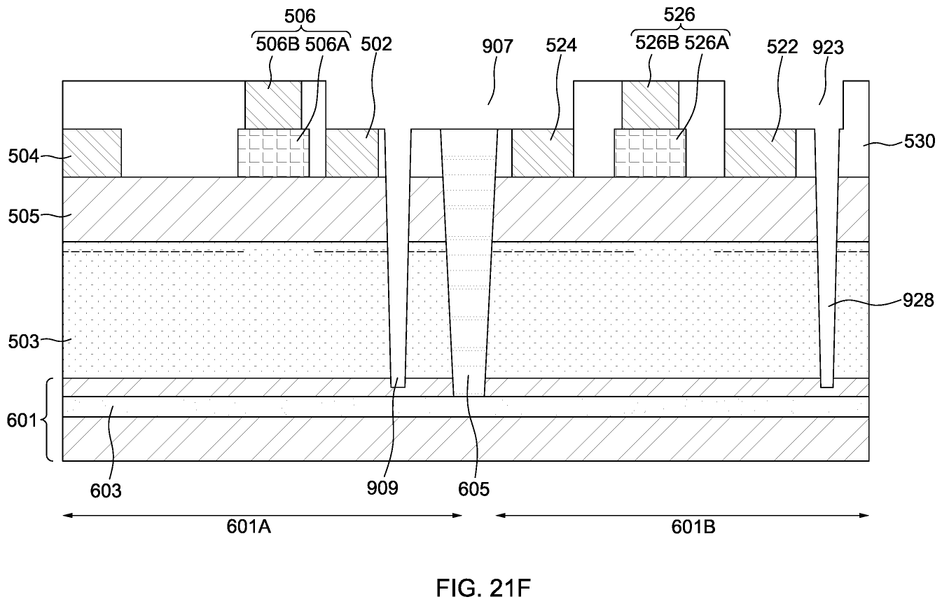

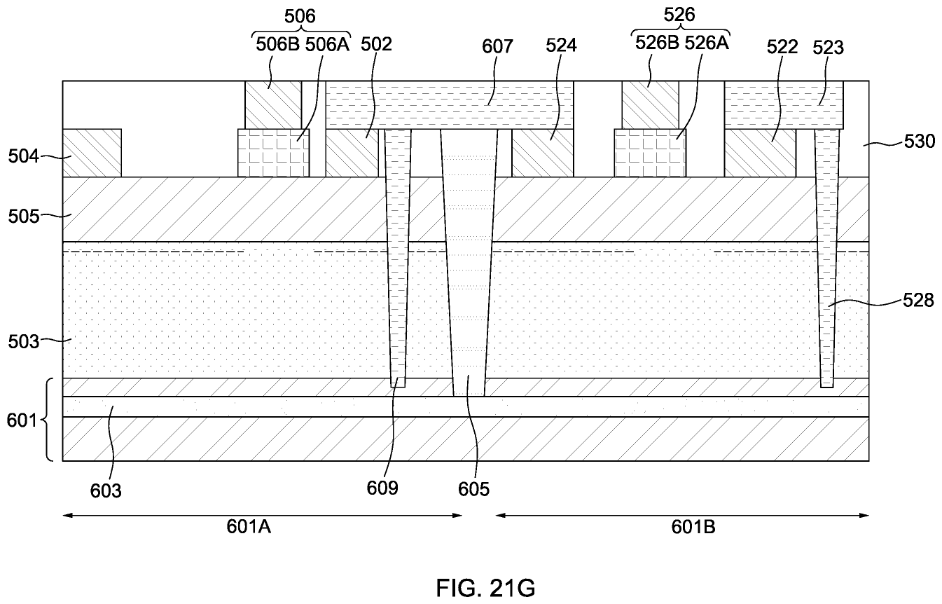

FIG. 21A, FIG. 21B, FIG. 21C, FIG. 21D, FIG. 21E, FIG. 21F and FIG. 21G illustrate some operations to manufacture the semiconductor device 7 in accordance with some embodiments of the present disclosure. As shown in FIG. 21A, a substrate 601 is provided. The substrate 601 includes a region 601A and a region 601B. The substrate 601 includes an insulating layer 603. The insulating layer 603 may be buried in the substrate 601. The insulating layer 603 may be a buried insulating layer. In some embodiments, the insulating layer 603 may be a buried oxide layer 603.

As shown in FIG. 21B, a semiconductor layer 503 is formed on the substrate 601. In some embodiments, before the formation of the semiconductor layer 503, one or more buffer layers (not shown) may be formed on the region 601A and the region 601B of the substrate 601. The semiconductor layer 503 may be formed on the one or more buffer layers. The semiconductor layer 503 is formed on the region 601A and the region 601B of the substrate 601. The semiconductor layer 503 may be formed by CVD and/or another suitable deposition operation. The semiconductor layer 505 is formed on the semiconductor layer 503. The semiconductor layer 505 may be formed by CVD and/or another suitable deposition operation.

As shown in FIG. 21C, a gate structure 506 is formed on the semiconductor layer 505. The gate structure 506 is formed on the region 601A of the substrate 601. The gate structure 506 may be formed by CVD, PVD, ALD and/or another suitable deposition operation. A gate structure 526 is formed on the semiconductor layer 505. The gate structure 526 is formed on the region 601B of the substrate 601. The gate structure 526 may be formed by CVD, PVD, ALD and/or another suitable deposition operation. In some embodiments, the gate structure 506 and the gate structure 526 may be formed simultaneously.

As shown in FIG. 21D, contacts 502, 504, 522, 524 are formed on the semiconductor layer 505. The contacts 502, 504 are formed on the region 601A of the substrate 601. The contacts 522, 524 are formed on the region 601B of the substrate 601. The contacts 502, 504, 522, 524 may be formed by CVD, PVD, ALD and/or another suitable deposition operation. A dielectric layer 530 is formed on the semiconductor layer 505. The dielectric layer 530 may be formed by CVD, PVD, and/or another suitable deposition operation. In some embodiments, the dielectric layer 530 may include multiple layers. In some embodiments, after the gate structure 506 and the gate structure 526 are formed, a first sublayer of the dielectric layer 530 is formed to cover the gate structure 506, the gate structure 526 and the semiconductor layer 505. In some embodiments, a portion of the first sublayer of the dielectric layer 530 is removed to form openings and the contacts 502, 504, 522, 524 are formed in the openings. A portion of the first sublayer of the dielectric layer 530 may be removed by etching and/or another suitable removing operation. In some embodiments, after the contacts 502, 504, 522, 524 are formed, a second sublayer of the dielectric layer 530 is formed to cover the contacts 502, 504, 522, 524.

As shown in FIG. 21E, an isolation structure 605 is formed between the region 601A and the region 601B of the substrate 601. The isolation structure 605 may be formed by forming a trench and depositing an insulating material in the trench. The trench may be formed by removing a portion of the dielectric layer 530, a portion of the semiconductor layer 505, a portion of the semiconductor layer 503 and a portion of the substrate 601 until the trench reaches the insulating layer 603. The trench may be formed by etching and/or another suitable removing operation. The trench may be filled with an insulating material by CVD, PVD, ALD and/or another suitable deposition operation. After the deposition of the insulating material in the trench, a planarization operation may be carried out. The planarization operation may be CMP. In some embodiments, an upper surface of the isolation structure 605 may be coplanar with an upper surface of the dielectric layer 530.

As shown in FIG. 21F, a trench 907 is formed on the contacts 502, 524. The trench 907 is formed by removing a portion of the dielectric layer 530 and a portion of the isolation structure 605. The trench 907 may be formed by etching and/or another suitable removing operation. A trench 923 is formed on the contacts 522. The trench 923 is formed by removing a portion of the dielectric layer 530. The trench 923 may be formed by etching and/or another suitable removing operation. A via 909 is formed by removing a portion of the dielectric layer 530, a portion of the semiconductor layer 505, a portion of the semiconductor layer 503 and a portion of the substrate 601. The via 909 extends from the trench 907 to the region 601A of the substrate 601. The via 909 terminates before reaching the insulating layer 603. The via 909 may be formed by etching and/or another suitable removing operation. A via 928 is formed by removing a portion of the dielectric layer 530, a portion of the semiconductor layer 505, a portion of the semiconductor layer 503 and a portion of the substrate 601. The via 928 extends from the trench 923 to the region 601B of the substrate 601. The via 928 terminates before reaching the insulating layer 603. The via 928 may be formed by etching and/or another suitable removing operation. In some embodiments, after the via 909 is formed, the trench 907 is formed. In some embodiments, after the via 928 is formed, the trench 923 is formed. In some embodiments, the via 909 and the via 928 may be formed simultaneously. In some embodiments, the trench 907 and the trench 923 may be formed simultaneously.

As shown in FIG. 21G, a conductive via 609 is formed by depositing a conductive material in the trench 909. The conductive via 609 may be formed by CVD, PVD, ALD, and/or another suitable deposition operation. A conductive wire 607 is formed on the contacts 502, 524 by depositing a conductive material in the trench 907. The conductive wire 607 may be formed by CVD, PVD, ALD, and/or another suitable deposition operation. A conductive via 528 is formed by depositing a conductive material in the trench 928. The conductive via 528 may be formed by CVD, PVD, ALD, and/or another suitable deposition operation. A conductive wire 523 is formed on the contact 522 by depositing a conductive material in the trench 923. The conductive wire 523 may be formed by CVD, PVD, ALD, and/or another suitable deposition operation. In some embodiments, the trench 907 and the via 909 may be simultaneously filled with a conductive material. In some embodiments, the trench 923 and the via 928 may be simultaneously filled with a conductive material. In some embodiments, the trench 907, the trench 923, the via 909 and the via 928 may be simultaneously filled with a conductive material. In some embodiments, the conductive wire 607 and the conductive via 609 may be formed in the same operation. In some embodiments, the conductive wire 523 and the conductive via 528 may be formed in the same operation. In some embodiments, the conductive wire 607, the conductive wire 523, the conductive via 609 and the conductive via 528 may be formed in the same operation. In some embodiments, after deposition of a conductive material in the trench 907 and the trench 923, a planarization operation is carried out to remove excess conductive material. The planarization operation may be CMP. In some embodiments, an upper surface of the conductive wire 607 may be coplanar with an upper surface of the dielectric layer 530. In some embodiments, an upper surface of the conductive wire 523 may be coplanar with an upper surface of the dielectric layer 530.

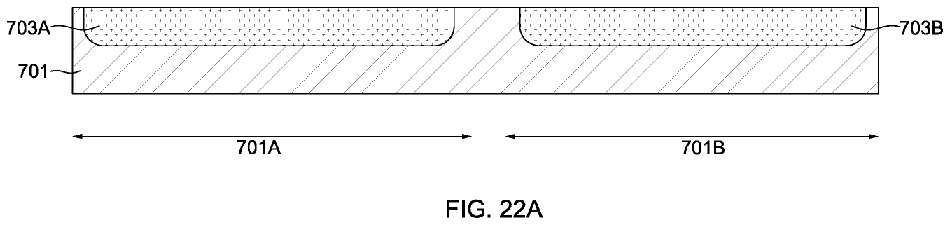

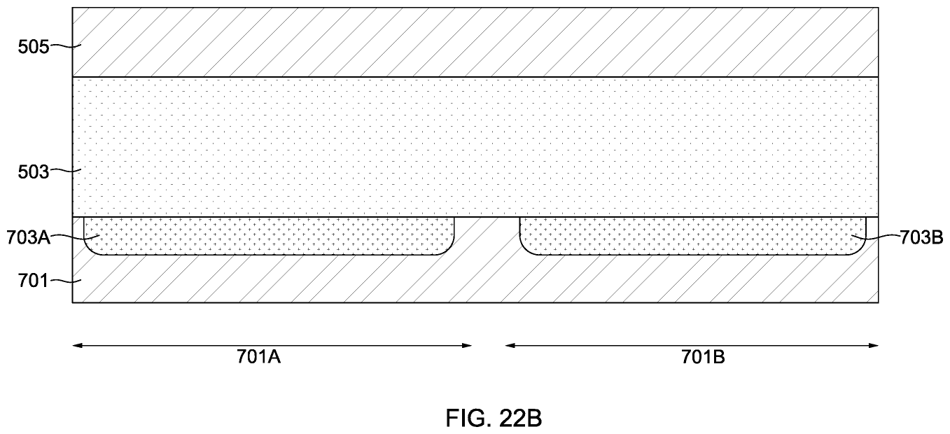

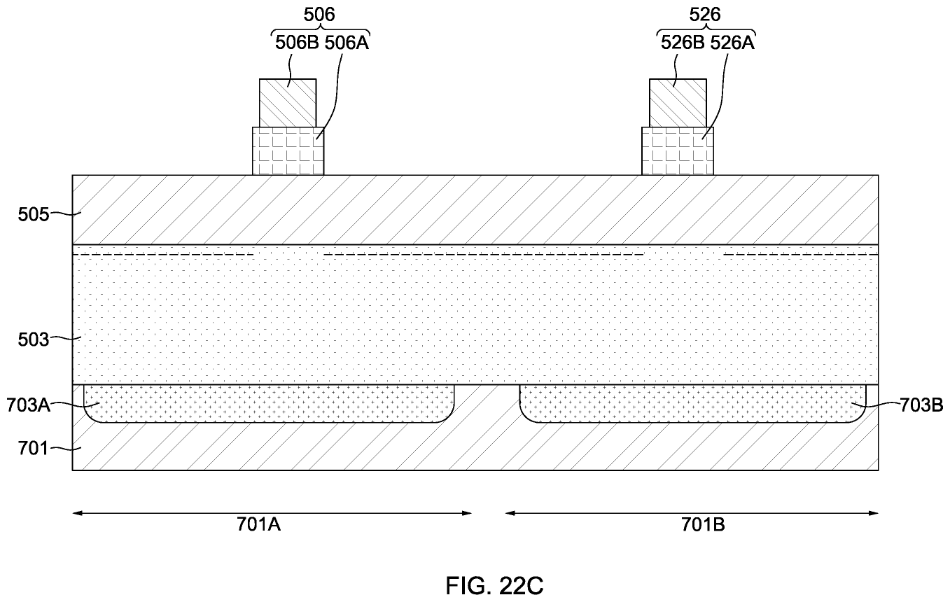

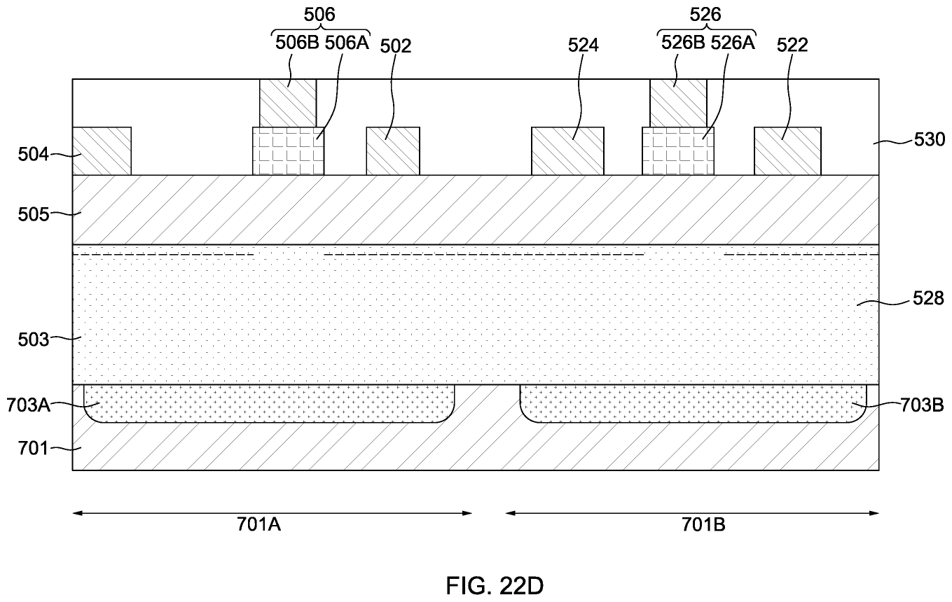

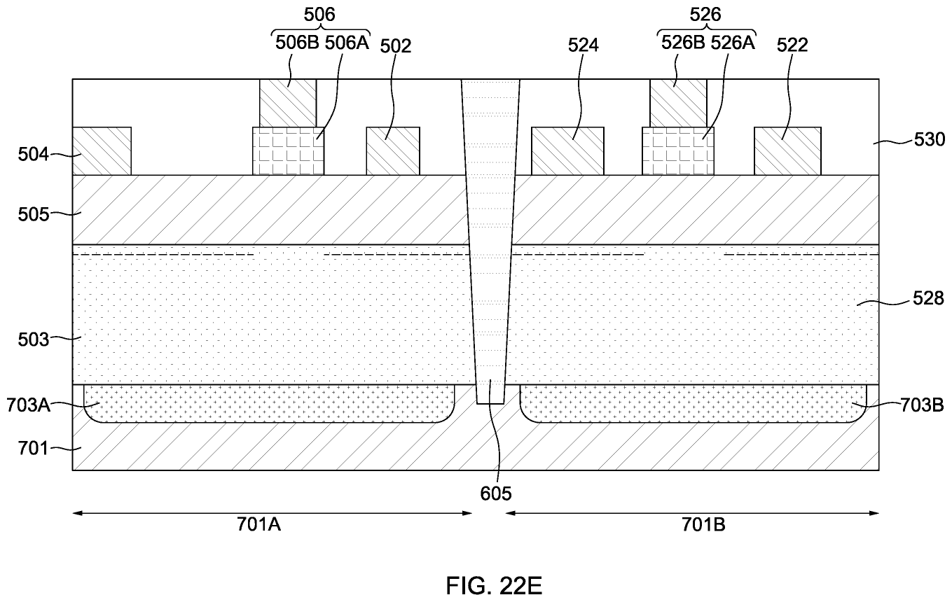

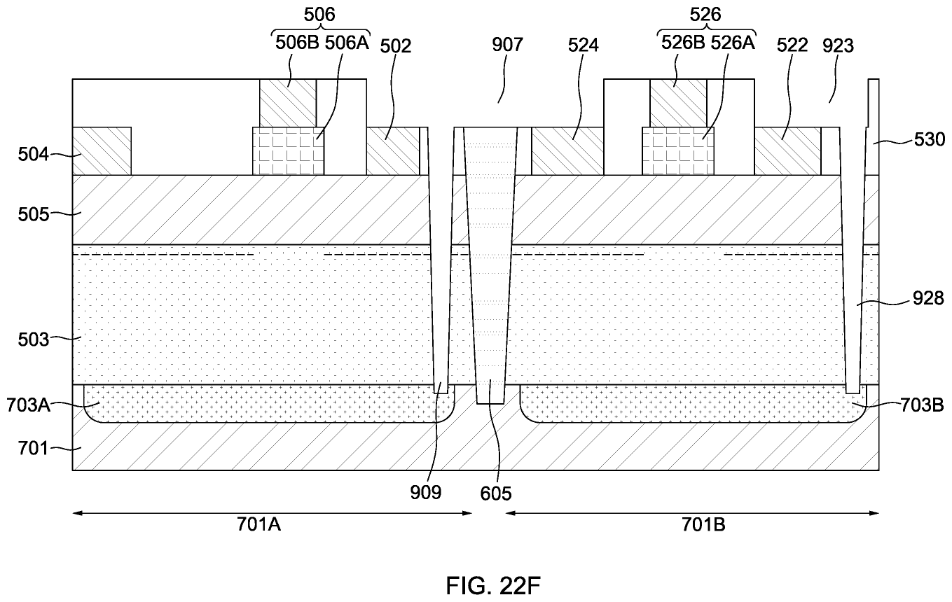

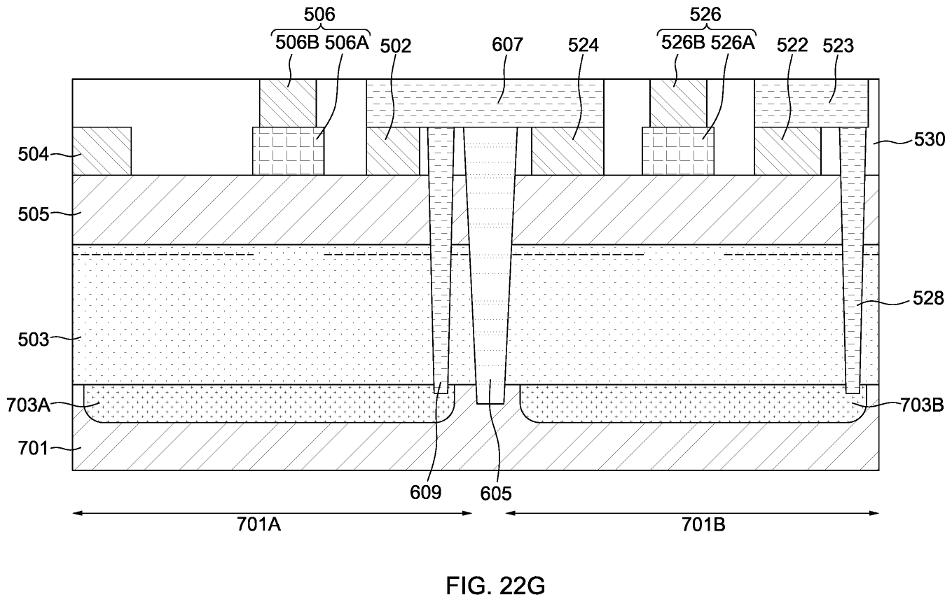

FIG. 22A, FIG. 22B, FIG. 22C, FIG. 22D, FIG. 22E, FIG. 22F and FIG. 22G illustrate some operations to manufacture the semiconductor device 7 in accordance with some embodiments of the present disclosure. As shown in FIG. 22A, a substrate 701 is provided. The substrate 701 includes a region 701A and a region 701B. The substrate 701 may be doped. An opposite-doped region 703A is formed in the region 701A of the substrate 701. The opposite-doped region 703A is doped with opposite polarity to the substrate 701. The opposite-doped region 703A may be formed by diffusion, ion implantation and/or another suitable doping operation. An opposite-doped region 703B is formed in the region 701B of the substrate 701. The opposite-doped region 703B is doped with opposite polarity to the substrate 701. The opposite-doped region 703B may be formed by diffusion, ion implantation and/or another suitable doping operation. An upper surface of the opposite-doped region 703A is coplanar with an upper surface of the substrate 701. An upper surface of the opposite-doped region 703B is coplanar with an upper surface of the substrate 701. In some embodiments, the opposite-doped region 703A and the opposite-doped region 703B may be formed simultaneously.

As shown in FIG. 22B, a semiconductor layer 503 is formed on the substrate 701. In some embodiments, before the formation of the semiconductor layer 503, one or more buffer layers (not shown) may be formed on the region 701A and the region 701B of the substrate 701. The semiconductor layer 503 may be formed on the one or more buffer layers. The semiconductor layer 503 is formed on the region 701A and the region 701B of the substrate 701. The semiconductor layer 503 may be formed by CVD and/or another suitable deposition operation. The semiconductor layer 505 is formed on the semiconductor layer 503. The semiconductor layer 505 may be formed by CVD and/or another suitable deposition operation.

As shown in FIG. 22C, a gate structure 506 is formed on the semiconductor layer 505. The gate structure 506 is formed on the region 701A of the substrate 701. The gate structure 506 may be formed on the opposite-doped region 703A. The gate structure 506 may be formed by CVD, PVD, ALD and/or another suitable deposition operation. A gate structure 526 is formed on the semiconductor layer 505. The gate structure 526 is formed on the region 701B of the substrate 701. The gate structure 526 may be formed on the opposite-doped region 703B. The gate structure 526 may be formed by CVD, PVD, ALD and/or another suitable deposition operation. In some embodiments, the gate structure 506 and the gate structure 526 may be formed simultaneously.

As shown in FIG. 22D, contacts 502, 504, 522, 524 are formed on the semiconductor layer 505. The contacts 502, 504 are formed on the region 701A of the substrate 701. The contacts 522, 524 are formed on the region 701B of the substrate 701. The contacts 502, 504, 522, 524 may be formed by CVD, PVD, ALD and/or another suitable deposition operation. A dielectric layer 530 is formed on the semiconductor layer 505. The dielectric layer 530 may be formed by CVD, PVD, and/or another suitable deposition operation. In some embodiments, the dielectric layer 530 may include multiple layers. In some embodiments, after the gate structure 506 and the gate structure 526 are formed, a first sublayer of the dielectric layer 530 is formed to cover the gate structure 506, the gate structure 526 and the semiconductor layer 505. In some embodiments, a portion of the first sublayer of the dielectric layer 530 is removed to form openings and the contacts 502, 504, 522, 524 are formed in the openings. A portion of the first sublayer of the dielectric layer 530 may be removed by etching and/or another suitable removing operation. In some embodiments, after the contacts 502, 504, 522, 524 are formed, a second sublayer of the dielectric layer 530 is formed to cover the contacts 502, 504, 522, 524.

As shown in FIG. 22E, an isolation structure 605 is formed between the region 701A and the region 701B of the substrate 701. The isolation structure 605 may be formed by forming a trench and depositing an insulating material in the trench. The trench may be formed by removing a portion of the dielectric layer 530, a portion of the semiconductor layer 505, a portion of the semiconductor layer 503 and a portion of the substrate 701. The trench may be formed by etching and/or another suitable removing operation. The trench may be filled with an insulating material by CVD, PVD, ALD and/or another suitable deposition operation. After the deposition of the insulating material in the trench, a planarization operation may be carried out. The planarization operation may be CMP. In some embodiments, an upper surface of the isolation structure 605 may be coplanar with an upper surface of the dielectric layer 530.

As shown in FIG. 22F, a trench 907 is formed on the contacts 502, 524. The trench 907 is formed by removing a portion of the dielectric layer 530 and a portion of the isolation structure 605. The trench 907 may be formed by etching and/or another suitable removing operation. A trench 923 is formed on the contacts 522. The trench 923 is formed by removing a portion of the dielectric layer 530. The trench 923 may be formed by etching and/or another suitable removing operation. A via 909 is formed by removing a portion of the dielectric layer 530, a portion of the semiconductor layer 505, a portion of the semiconductor layer 503 and a portion of the opposite-doped region 703A. The via 909 extends from the trench 907 to the opposite-doped region 703A. The via 909 terminates within the opposite-doped region 703A. The via 909 may be formed by etching and/or another suitable removing operation. A via 928 is formed by removing a portion of the dielectric layer 530, a portion of the semiconductor layer 505, a portion of the semiconductor layer 503 and a portion of the opposite-doped region 703B. The via 928 extends from the trench 923 to the opposite-doped region 703B. The via 928 terminates within the opposite-doped region 703B. The via 928 may be formed by etching and/or another suitable removing operation. In some embodiments, after the via 909 is formed, the trench 907 is formed. In some embodiments, after the via 928 is formed, the trench 923 is formed. In some embodiments, the via 909 and the via 928 may be formed simultaneously. In some embodiments, the trench 907 and the trench 923 may be formed simultaneously.

As shown in FIG. 22G, a conductive via 609 is formed by depositing a conductive material in the trench 909. The conductive via 609 may be formed by CVD, PVD, ALD, and/or another suitable deposition operation. A conductive wire 607 is formed on the contacts 502, 524 by depositing a conductive material in the trench 907. The conductive wire 607 may be formed by CVD, PVD, ALD, and/or another suitable deposition operation. A conductive via 528 is formed by depositing a conductive material in the trench 928. The conductive via 528 may be formed by CVD, PVD, ALD, and/or another suitable deposition operation. A conductive wire 523 is formed on the contact 522 by depositing a conductive material in the trench 923. The conductive wire 523 may be formed by CVD, PVD, ALD, and/or another suitable deposition operation. In some embodiments, the trench 907 and the via 909 may be simultaneously filled with a conductive material. In some embodiments, the trench 923 and the via 928 may be simultaneously filled with a conductive material. In some embodiments, the trench 907, the trench 923, the via 909 and the via 928 may be simultaneously filled with a conductive material. In some embodiments, the conductive wire 607 and the conductive via 609 may be formed in the same operation. In some embodiments, the conductive wire 523 and the conductive via 528 may be formed in the same operation. In some embodiments, the conductive wire 607, the conductive wire 523, the conductive via 609 and the conductive via 528 may be formed in the same operation. In some embodiments, after deposition of a conductive material in the trench 907 and the trench 923, a planarization operation is carried out to remove excess conductive material. The planarization operation may be CMP. In some embodiments, an upper surface of the conductive wire 607 may be coplanar with an upper surface of the dielectric layer 530. In some embodiments, an upper surface of the conductive wire 523 may be coplanar with an upper surface of the dielectric layer 530.

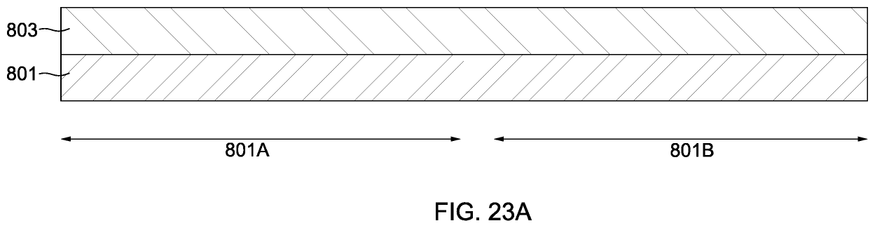

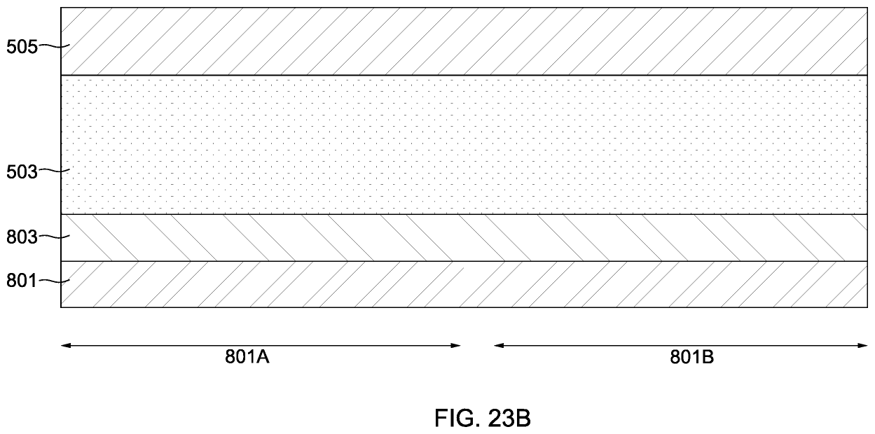

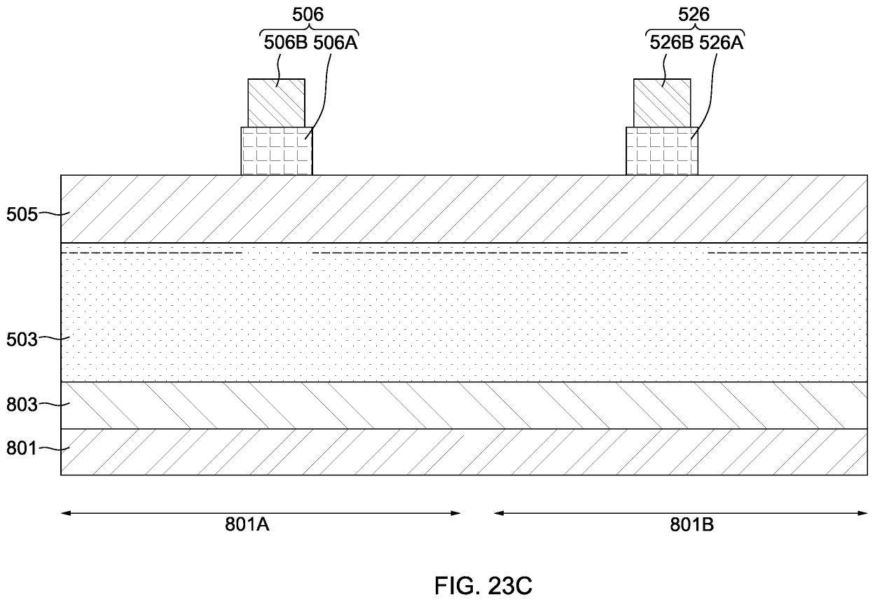

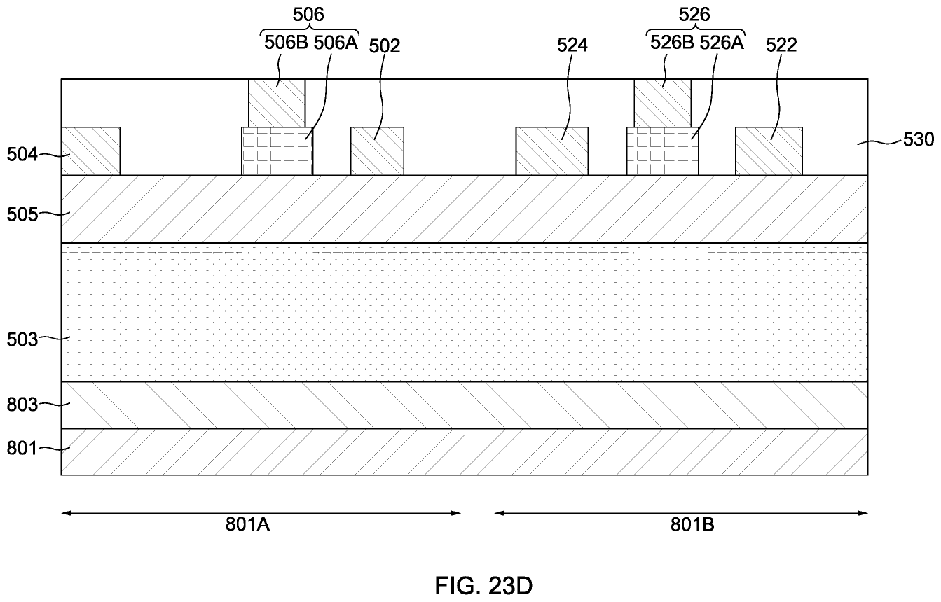

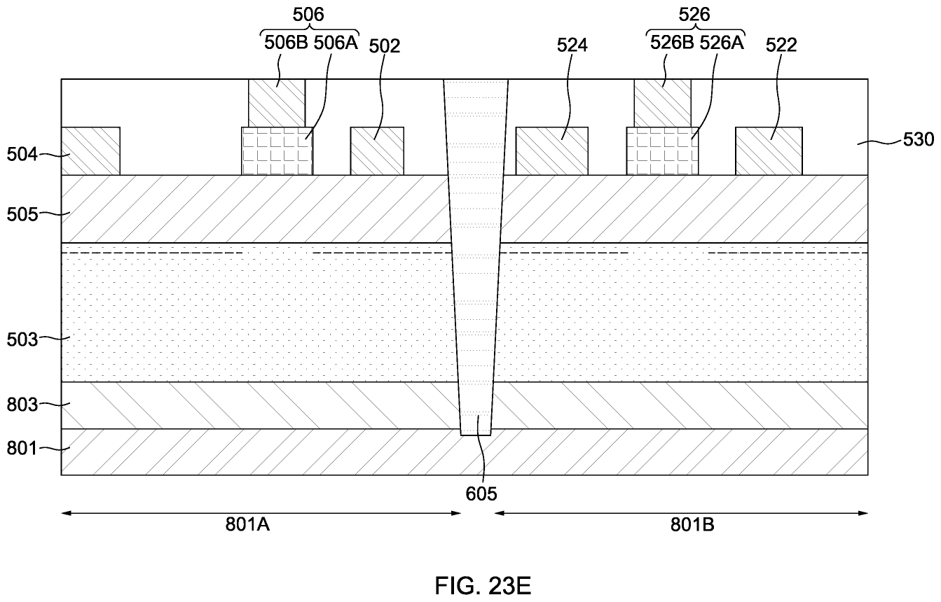

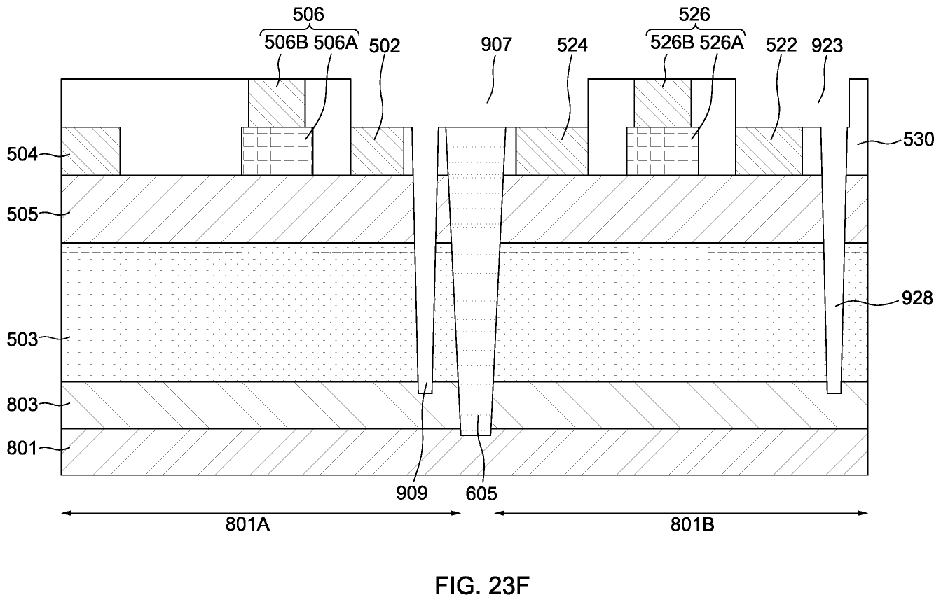

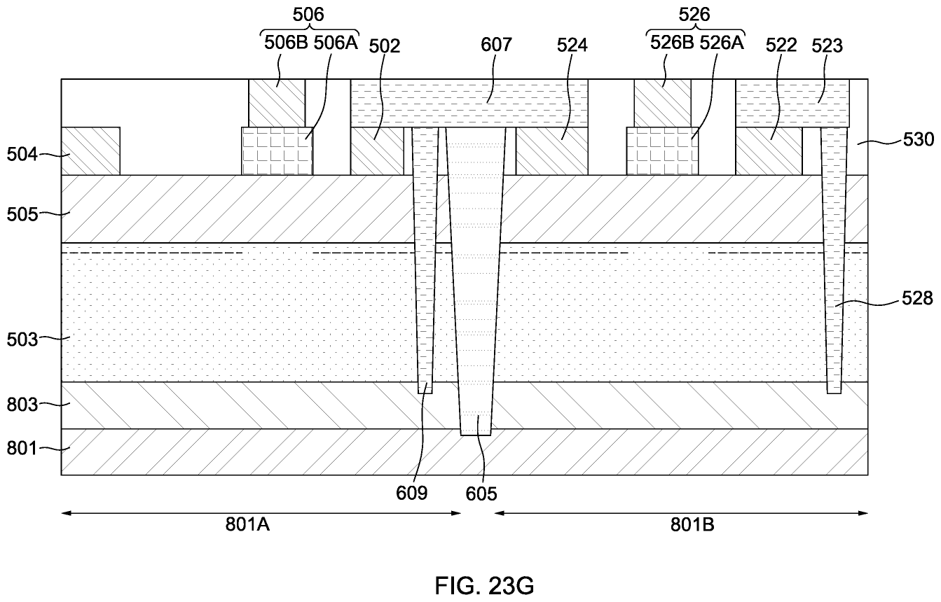

FIG. 23A, FIG. 23B, FIG. 23C, FIG. 23D, FIG. 23E, FIG. 23F and FIG. 23G illustrate some operations to manufacture the semiconductor device 8 in accordance with some embodiments of the present disclosure. As shown in FIG. 23A, a substrate 801 is provided. The substrate 801 includes a region 801A and a region 801B. The substrate 801 may be doped. A doped semiconductor layer 803 is formed on the region 801A and the region 801B of the substrate 801. The doped semiconductor layer 803 has polarity opposite to the substrate 801. In some embodiments, the doped semiconductor layer 803 may be formed by epitaxial growth on the substrate 801. In some embodiments, the doped semiconductor layer 803 may be formed by CVD, PVD, ALD, and/or another suitable deposition operation. In some embodiments, the doped semiconductor layer 803 may be formed on the region 801A and the region 801B by extrinsically doping the substrate 801. In some embodiments, the doped semiconductor layer 803 may be formed by ion implantation into the substrate 801. Due to opposite polarity between the doped semiconductor layer 803 and in the substrate 801, a p-n junction is formed between the doped semiconductor layer 803 and the substrate 801.

As shown in FIG. 23B, a semiconductor layer 503 is formed on the doped semiconductor layer 803. In some embodiments, before the formation of the semiconductor layer 803, one or more buffer layers (not shown) may be formed on the region 801A and the region 801B of the substrate 801. The semiconductor layer 503 may be formed on the one or more buffer layers. The semiconductor layer 503 is formed on the region 801A and the region 801B of the substrate 801. The semiconductor layer 503 may be formed by CVD and/or another suitable deposition operation. The semiconductor layer 505 is formed on the semiconductor layer 503. The semiconductor layer 505 may be formed by CVD and/or another suitable deposition operation.

As shown in FIG. 23C, a gate structure 506 is formed on the semiconductor layer 505. The gate structure 506 is formed on the region 801A of the substrate 801. The gate structure 506 may be formed by CVD, PVD, ALD and/or another suitable deposition operation. A gate structure 526 is formed on the semiconductor layer 505. The gate structure 526 is formed on the region 801B of the substrate 801. The gate structure 526 may be formed by CVD, PVD, ALD and/or another suitable deposition operation. In some embodiments, the gate structure 506 and the gate structure 526 may be formed simultaneously.

As shown in FIG. 23D, contacts 502, 504, 522, 524 are formed on the semiconductor layer 505. The contacts 502, 504 are formed on the region 801A of the substrate 801. The contacts 522, 524 are formed on the region 801B of the substrate 801. The contacts 502, 504, 522, 524 may be formed by CVD, PVD, ALD and/or another suitable deposition operation. A dielectric layer 530 is formed on the semiconductor layer 505. The dielectric layer 530 may be formed by CVD, PVD, and/or another suitable deposition operation. In some embodiments, the dielectric layer 530 may include multiple layers. In some embodiments, after the gate structure 506 and the gate structure 526 are formed, a first sublayer of the dielectric layer 530 is formed to cover the gate structure 506, the gate structure 526 and the semiconductor layer 505. In some embodiments, a portion of the first sublayer of the dielectric layer 530 is removed to form openings and the contacts 502, 504, 522, 524 are formed in the openings. A portion of the first sublayer of the dielectric layer 530 may be removed by etching and/or another suitable removing operation. In some embodiments, after the contacts 502, 504, 522, 524 are formed, a second sublayer of the dielectric layer 530 is formed to cover the contacts 502, 504, 522, 524.

As shown in FIG. 23E, an isolation structure 605 is formed between the region 801A and the region 801B of the substrate 801. The isolation structure 605 may be formed by forming a trench and depositing an insulating material in the trench. The trench may be formed by removing a portion of the dielectric layer 530, a portion of the semiconductor layer 505, a portion of the semiconductor layer 503, a portion of the doped semiconductor layer 803 and a portion of the substrate 801. The trench may be formed by etching and/or another suitable removing operation. The trench may be filled with an insulating material by CVD, PVD, ALD and/or another suitable deposition operation. After the deposition of the insulating material in the trench, a planarization operation may be carried out. The planarization operation may be CMP. In some embodiments, an upper surface of the isolation structure 605 may be coplanar with an upper surface of the dielectric layer 530.

As shown in FIG. 23F, a trench 907 is formed on the contacts 502, 524. The trench 907 is formed by removing a portion of the dielectric layer 530 and a portion of the isolation structure 605. The trench 907 may be formed by etching and/or another suitable removing operation. A trench 923 is formed on the contacts 522. The trench 923 is formed by removing a portion of the dielectric layer 530. The trench 923 may be formed by etching and/or another suitable removing operation. A via 909 is formed by removing a portion of the dielectric layer 530, a portion of the semiconductor layer 505, a portion of the semiconductor layer 503 and a portion of the doped semiconductor layer 803. The via 909 extends from the trench 907 to the doped semiconductor layer 803 on the region 801A of the substrate 801. The via 909 terminates within the doped semiconductor layer 803 on the region 801A of the substrate 801. The via 909 may be formed by etching and/or another suitable removing operation. A via 928 is formed by removing a portion of the dielectric layer 530, a portion of the semiconductor layer 505, a portion of the semiconductor layer 503 and a portion of the doped semiconductor layer 803. The via 928 extends from the trench 923 to the doped semiconductor layer 803 on the region 801B of the substrate 801. The via 928 terminates within the doped semiconductor layer 803 on the region 801B of the substrate 801. The via 928 may be formed by etching and/or another suitable removing operation. In some embodiments, after the via 909 is formed, the trench 907 is formed. In some embodiments, after the via 928 is formed, the trench 923 is formed. In some embodiments, the via 909 and the via 928 may be formed simultaneously. In some embodiments, the trench 907 and the trench 923 may be formed simultaneously.

As shown in FIG. 23G, a conductive via 609 is formed by depositing a conductive material in the trench 909. The conductive via 609 may be formed by CVD, PVD, ALD, and/or another suitable deposition operation. A conductive wire 607 is formed on the contacts 502, 524 by depositing a conductive material in the trench 907. The conductive wire 607 may be formed by CVD, PVD, ALD, and/or another suitable deposition operation. A conductive via 528 is formed by depositing a conductive material in the trench 928. The conductive via 528 may be formed by CVD, PVD, ALD, and/or another suitable deposition operation. A conductive wire 523 is formed on the contact 522 by depositing a conductive material in the trench 923. The conductive wire 523 may be formed by CVD, PVD, ALD, and/or another suitable deposition operation. In some embodiments, the trench 907 and the via 909 may be simultaneously filled with a conductive material. In some embodiments, the trench 923 and the via 928 may be simultaneously filled with a conductive material. In some embodiments, the trench 907, the trench 923, the via 909 and the via 928 may be simultaneously filled with a conductive material. In some embodiments, the conductive wire 607 and the conductive via 609 may be formed in the same operation. In some embodiments, the conductive wire 523 and the conductive via 528 may be formed in the same operation. In some embodiments, the conductive wire 607, the conductive wire 523, the conductive via 609 and the conductive via 528 may be formed in the same operation. In some embodiments, after deposition of a conductive material in the trench 907 and the trench 923, a planarization operation is carried out to remove excess conductive material. The planarization operation may be CMP. In some embodiments, an upper surface of the conductive wire 607 may be coplanar with an upper surface of the dielectric layer 530. In some embodiments, an upper surface of the conductive wire 523 may be coplanar with an upper surface of the dielectric layer 530.

Some embodiments of the present disclosure are described as follows.

Embodiment 1-1: A semiconductor device, comprising:
a substrate;
a first nitride semiconductor layer on the substrate;
a second nitride semiconductor layer on the first nitride semiconductor layer and having a band gap greater than a band gap of the first nitride semiconductor layer;
a drain contact on the second nitride semiconductor layer;
a source contact on the second nitride semiconductor layer;
a common contact on the second nitride semiconductor layer and between the drain contact and the source contact;
a first gate structure on the second nitride semiconductor layer and between the drain contact and the common contact;
a second gate structure on the second nitride semiconductor layer and between the common contact and the source contact;
a conductive wire on the source contact;
a dielectric layer on the second nitride semiconductor layer and covering a portion of a lateral surface of the conductive wire; and
a conductive via connected to the conductive wire,
wherein the conductive via extends through a portion of the dielectric layer, the second nitride semiconductor layer, and the first nitride semiconductor layer to the substrate.

Embodiment 1-2: The semiconductor device of any of the preceding embodiments, wherein the conductive wire has a lower surface facing the substrate and extending beyond the source contact and the conductive via is connected to the lower surface of the conductive wire.

Embodiment 1-3: The semiconductor device of any of the preceding embodiments, wherein the dielectric layer covers a portion of the lower surface of the conductive wire.

Embodiment 1-4: The semiconductor device of any of the preceding embodiments, wherein a portion of the dielectric layer is between the source contact and the conductive via.

Embodiment 1-5: The semiconductor device of any of the preceding embodiments, wherein a portion of the dielectric layer is between the conductive wire and the second nitride semiconductor layer.

Embodiment 1-6: The semiconductor device of any of the preceding embodiments, further comprising a second conductive wire on the common contact, wherein the dielectric layer covers a portion of the second conductive wire.

Embodiment 1-7: The semiconductor device of any of the preceding embodiments, wherein a shortest distance between the first gate structure and the common contact is smaller than a shortest distance between the first gate structure and the drain contact.

Embodiment 1-8: The semiconductor device of any of the preceding embodiments, wherein a shortest distance between the second gate structure and the common contact is greater than a shortest distance between the second gate structure and the source contact.

Embodiment 1-9: The semiconductor device of any of the preceding embodiments, wherein a shortest distance between the first gate structure and the common contact is smaller than a shortest distance between the second gate structure and the common contact.

Embodiment 1-10: The semiconductor device of any of the preceding embodiments, wherein the source contact is between the second gate structure and the conductive via.

Embodiment 1-11: The semiconductor device of any of the preceding embodiments, wherein the conductive wire is between the source contact and the conductive via.

Embodiment 1-12: The semiconductor device of any of the preceding embodiments, wherein the first gate structure comprises a doped nitride semiconductor element on the second nitride semiconductor layer and a gate contact on the doped nitride semiconductor element.

Embodiment 1-13: The semiconductor device of any of the preceding embodiments, wherein the second gate structure comprises a doped nitride semiconductor element on the second nitride semiconductor layer and a gate contact on the doped nitride semiconductor element.

Embodiment 1-14: A method of manufacturing a semiconductor device, comprising:
providing a substrate;
forming a first nitride semiconductor layer on the substrate;
forming a second nitride semiconductor layer on the first nitride semiconductor layer, wherein the second nitride semiconductor layer has a band gap greater than a band gap of the first nitride semiconductor layer;
forming a drain contact and a source contact on the second nitride semiconductor layer;
forming a common contact on the second nitride semiconductor layer and between the drain contact and the source contact;
forming a first gate structure on the second nitride semiconductor layer and between the drain contact and the common contact;
forming a second gate structure on the second nitride semiconductor layer and between the common contact and the source contact;
forming a conductive wire on the source contact;
forming a dielectric layer on the second nitride semiconductor layer, wherein the dielectric layer covers a portion of a lateral surface of the conductive wire; and
forming a conductive via connected to the conductive wire, wherein the conductive via extends through a portion of the dielectric layer, the second nitride semiconductor layer, and the first nitride semiconductor layer to the substrate.

Embodiment 1-15: The method of any of the preceding embodiments, wherein the conductive wire has a lower surface facing the substrate and extending beyond the source contact and the conductive via is connected to the lower surface of the conductive wire.

Embodiment 1-16: The method of any of the preceding embodiments, wherein the dielectric layer covers a portion of the lower surface of the conductive wire.

Embodiment 1-17: The method of any of the preceding embodiments, wherein a portion of the dielectric layer is between the source contact and the conductive via.

Embodiment 1-18: The method of any of the preceding embodiments, further comprising:

forming a second conductive wire on the common contact, wherein the dielectric layer covers a portion of the second conductive wire.

Embodiment 1-19: The method of any of the preceding embodiments, wherein a shortest distance between the first gate structure and the common contact is smaller than a shortest distance between the first gate structure and the drain contact.

Embodiment 1-20: The method of any of the preceding embodiments, wherein a shortest distance between the second gate structure and the common contact is greater than a shortest distance between the second gate structure and the source contact.

Embodiment 1-21: A semiconductor device, comprising:
a substrate;
a first nitride semiconductor layer on the substrate;
a second nitride semiconductor layer on the first nitride semiconductor layer and having a band gap greater than a band gap of the first nitride semiconductor layer;
a drain contact on the second nitride semiconductor layer;
a source contact on the second nitride semiconductor layer;
a common contact on the second nitride semiconductor layer and between the drain contact and the source contact;
a first gate structure on the second nitride semiconductor layer and between the drain contact and the common contact; and
a second gate structure on the second nitride semiconductor layer and between the common contact and the source contact,
wherein the source contact is electrically connected to the substrate through a conductive via, and a shortest distance between the first gate structure and the common contact is smaller than a shortest distance between the second gate structure and the common contact.

Embodiment 1-22: The semiconductor device of any of the preceding embodiments, wherein the shortest distance between the first gate structure and the common contact is smaller than a shortest distance between the first gate structure and the drain contact.

Embodiment 1-23: The semiconductor device of any of the preceding embodiments, wherein the shortest distance between the second gate structure and the common contact is greater than a shortest distance between the second gate structure and the source contact.

Embodiment 1-24: The semiconductor device of any of the preceding embodiments, further comprising a dielectric layer on the second nitride semiconductor layer, wherein the dielectric layer covers a portion of a lateral surface of the conductive via, the lateral surface facing the source contact or the drain contact.

Embodiment 1-25: The semiconductor device of any of the preceding embodiments, wherein a portion of the dielectric layer is between the source contact and the conductive via.

Embodiment 1-26: The semiconductor device of any of the preceding embodiments, further comprising a conductive wire on the source contact, wherein the conductive via is connected to the conductive wire.

Embodiment 1-27: The semiconductor device of any of the preceding embodiments, wherein the conductive wire has a lower surface facing the substrate and extending beyond the source contact, and the conductive via is connected to the lower surface of the conductive wire.

Embodiment 2-1: A semiconductor device, comprising:
a substrate comprising an insulating layer buried in the substrate, the substrate having a first region and a second region;
a first nitride semiconductor layer on the substrate;
a second nitride semiconductor layer on the first nitride semiconductor layer and having a band gap greater than a band gap of the first nitride semiconductor layer;
an isolation structure disposed between the first region and the second region of the substrate and extending through the second nitride semiconductor layer and the first nitride semiconductor layer to the insulating layer,
a first source contact and a first drain contact on the second nitride semiconductor layer on the first region of the substrate;
a first gate structure on the second nitride semiconductor layer and between the first source contact and the first drain contact;
a second source contact and a second drain contact on the second nitride semiconductor layer on the second region of the substrate;
a second gate structure on the second nitride semiconductor layer and between the second source contact and the second drain contact; and
a first conductive wire disposed on and connecting the first source contact and the second drain contact.

Embodiment 2-2: The semiconductor device of any of the preceding embodiments, wherein the first source contact is between the first drain contact and the second drain contact.

Embodiment 2-3: The semiconductor device of any of the preceding embodiments, wherein the second drain contact is between the first source contact and the second source contact.

Embodiment 2-4: The semiconductor device of any of the preceding embodiments, further comprising a first conductive via connecting the first conductive wire to the first region of the substrate.

Embodiment 2-5: The semiconductor device of any of the preceding embodiments, wherein the first conductive via is between the first source contact and the isolation structure.

Embodiment 2-6: The semiconductor device of any of the preceding embodiments, further comprising a second conductive wire on the second source contact and a second conductive via connecting the second conductive wire to the second region of the substrate.

Embodiment 2-7: The semiconductor device of any of the preceding embodiments, wherein the second conductive wire has a lower surface facing the substrate and connected to the second source contact and the second conductive via.

Embodiment 2-8: The semiconductor device of any of the preceding embodiments, wherein the second source contact is between the second gate structure and the second conductive via.

Embodiment 2-9: The semiconductor device of any of the preceding embodiments, further comprising a dielectric layer on the second nitride semiconductor layer, wherein the dielectric layer covers a portion of a lateral surface of the first conductive wire.

Embodiment 2-10: The semiconductor device of any of the preceding embodiments, further comprising a first conductive via connected to the first conductive wire, wherein the first conductive via extends through a portion of the dielectric layer, the second nitride semiconductor layer and the first nitride semiconductor layer to the first region of the substrate.

Embodiment 2-11: The semiconductor device of any of the preceding embodiments, further comprising a second conductive wire on the second source contact and a second conductive via connected to the second conductive wire, wherein the second conductive via extends through a portion of the dielectric layer, the second nitride semiconductor layer and the first nitride semiconductor layer to the second region of the substrate.

Embodiment 2-12: The semiconductor device of any of the preceding embodiments, wherein the dielectric layer covers a portion of a lateral surface of the second conductive wire.

Embodiment 2-13: The semiconductor device of any of the preceding embodiments, wherein a portion of the dielectric layer is between the second source contact and the second conductive via.

Embodiment 2-14: The semiconductor device of any of the preceding embodiments, wherein the first gate structure comprises a first doped nitride semiconductor element on the second nitride semiconductor layer and a first gate contact on the first doped nitride semiconductor element.

Embodiment 2-15: The semiconductor device of any of the preceding embodiments, wherein the second gate structure comprises a second doped nitride semiconductor element on the second nitride semiconductor layer and a second gate contact on the second doped nitride semiconductor element.

Embodiment 2-16: A method of manufacturing a semiconductor device, comprising:
providing a substrate comprising an insulating layer buried in the substrate, the substrate having a first region and a second region;
forming a first nitride semiconductor layer on the substrate;
forming a second nitride semiconductor layer on the first nitride semiconductor layer, wherein the second nitride semiconductor layer has a band gap greater than a band gap of the first nitride semiconductor layer;
forming an isolation structure between the first region and the second region of the substrate, the isolation structure extending through the second nitride semiconductor layer and the first nitride semiconductor layer to the insulating layer;
forming a first source contact and a first drain contact on the second nitride semiconductor layer on the first region of the substrate;
forming a first gate structure on the second nitride semiconductor layer and between the first source contact and the first drain contact;
forming a second source contact and a second drain contact on the second nitride semiconductor layer on the second region of the substrate;
forming a second gate structure on the second nitride semiconductor layer and between the second source contact and the second drain contact; and
forming a first conductive wire on the first source contact and the second drain contact, wherein the first conductive wire connects the first source contact and the second drain contact.

Embodiment 2-17: The method of any of the preceding embodiments, further comprising forming a first conductive via connecting the first conductive wire to the first region of the substrate.

Embodiment 2-18: The method of any of the preceding embodiments, further comprising forming a second conductive wire on the second source contact and a second conductive via connecting the second conductive wire to the second region of the substrate.

Embodiment 2-19: The method of any of the preceding embodiments, further comprising forming a dielectric layer on the second nitride semiconductor layer, wherein the dielectric layer covers a portion of a lateral surface of the first conductive wire.

Embodiment 2-20: The method of any of the preceding embodiments, further comprising forming a dielectric layer on the second nitride semiconductor layer, wherein the dielectric layer covers a portion of a lateral surface of the second conductive wire.

Embodiment 2-21: A semiconductor device, comprising: a substrate comprising an insulating layer buried in the substrate, the substrate having a first region and a second region;
a first nitride semiconductor layer on the substrate;
a second nitride semiconductor layer on the first nitride semiconductor layer and having a band gap greater than a band gap of the first nitride semiconductor layer;
an isolation structure surrounding the first region of the substrate;
a first source contact and a first drain contact on the second nitride semiconductor layer on the first region of the substrate;
a first gate structure on the second nitride semiconductor layer and between the first source contact and the first drain contact;
a second source contact and a second drain contact on the second nitride semiconductor layer on the second region of the substrate;
a second gate structure on the second nitride semiconductor layer and between the second source contact and the second drain contact; and
a first conductive wire disposed on and connecting the first source contact and the second drain contact,
wherein a projection of the first conductive wire perpendicular to an upper surface of the substrate overlaps the isolation structure, the upper surface facing the first nitride semiconductor layer.

Embodiment 2-22: The semiconductor device of any of the preceding embodiments, wherein the isolation structure extends through the second nitride semiconductor layer and the first nitride semiconductor layer to the insulating layer.

Embodiment 2-23: The semiconductor device of any of the preceding embodiments, further comprising a first conductive via connecting the first conductive wire to the first region of the substrate.

Embodiment 2-24: The semiconductor device of any of the preceding embodiments, further comprising a second conductive wire on the second source contact and a second conductive via connecting the second conductive wire to the second region of the substrate.

Embodiment 2-25: The semiconductor device of any of the preceding embodiments, further comprising a dielectric layer on the second nitride semiconductor layer, wherein the dielectric layer covers a portion of a lateral surface of the first conductive wire.

Embodiment 3-1: A semiconductor device, comprising:
a substrate having a first region and a second region;
a first doped region in the first region of the substrate, wherein the first doped region has opposite polarity to the substrate;
a second doped region in the second region of the substrate, wherein the second doped region has opposite polarity to the substrate;
a first nitride semiconductor layer on the substrate;
a second nitride semiconductor layer on the first nitride semiconductor layer and having a band gap greater than a band gap of the first nitride semiconductor layer;
an isolation structure disposed between the first region and the second region of the substrate and extending through the second nitride semiconductor layer and the first nitride semiconductor layer to the substrate;
a first source contact and a first drain contact on the second nitride semiconductor layer on the first region of the substrate;
a first gate structure on the second nitride semiconductor layer and between the first source contact and the first drain contact;
a second source contact and a second drain contact on the second nitride semiconductor layer on the second region of the substrate;
a second gate structure on the second nitride semiconductor layer and between the second source contact and the second drain contact; and
a first conductive wire disposed on and connecting the first source contact and the second drain contact.

Embodiment 3-2: The semiconductor device of any of the preceding embodiments, wherein the first source contact is between the first drain contact and the second drain contact.

Embodiment 3-3: The semiconductor device of any of the preceding embodiments, wherein the second drain contact is between the first source contact and the second source contact.

Embodiment 3-4: The semiconductor device of any of the preceding embodiments, further comprising a first conductive via connecting the first conductive wire to the first doped region.

Embodiment 3-5: The semiconductor device of any of the preceding embodiments, wherein the first conductive via is between the first contact source and the isolation structure.

Embodiment 3-6: The semiconductor device of any of the preceding embodiments, further comprising a second conductive wire on the second source contact and a second conductive via connecting the second conductive wire to the second doped region.

Embodiment 3-7: The semiconductor device of any of the preceding embodiments, wherein the second conductive wire has a lower surface facing the substrate and connected to the second source contact and the second conductive via.

Embodiment 3-8: The semiconductor device of any of the preceding embodiments, wherein the second contact source is between the second gate structure and the second conductive via.

Embodiment 3-9: The semiconductor device of any of the preceding embodiments, further comprising a dielectric layer on the second nitride semiconductor layer, wherein the dielectric layer covers a portion of a lateral surface of the first conductive wire.

Embodiment 3-10: The semiconductor device of any of the preceding embodiments, further comprising a first conductive via connected to the first conductive wire, wherein the first conductive via extends through a portion of the dielectric layer, the second nitride semiconductor layer and the first nitride semiconductor layer to the first doped region.

Embodiment 3-11: The semiconductor device of any of the preceding embodiments, further comprising a second conductive wire on the second source contact and a second conductive via connected to the second conductive wire, wherein the second conductive via extends through a portion of the dielectric layer, the second nitride semiconductor layer and the first nitride semiconductor layer to the second doped region.

Embodiment 3-12: The semiconductor device of any of the preceding embodiments, wherein the dielectric layer covers a portion of a lateral surface of the second conductive wire.

Embodiment 3-13: The semiconductor device of any of the preceding embodiments, wherein a portion of the dielectric layer is between the second source contact and the second conductive via.

Embodiment 3-14: The semiconductor device of any of the preceding embodiments, wherein the first gate structure comprises a first doped nitride semiconductor element on the second nitride semiconductor layer and a first gate contact on the first doped nitride semiconductor element.

Embodiment 3-15: The semiconductor device of any of the preceding embodiments, wherein the second gate structure comprises a second doped nitride semiconductor element on the second nitride semiconductor layer and a second gate contact on the second doped nitride semiconductor element.

Embodiment 3-16: A method of manufacturing a semiconductor device, comprising:
providing a substrate having a first region and a second region;
forming a first doped region in the first region of the substrate, wherein the first doped region has opposite polarity to the substrate;
forming a second doped region in the second region of the substrate, wherein the second doped region has opposite polarity to the substrate;
forming a first nitride semiconductor layer on the substrate;
forming a second nitride semiconductor layer on the first nitride semiconductor layer, wherein the second nitride semiconductor layer has a band gap greater than a band gap of the first nitride semiconductor layer;
forming an isolation structure between the first region and the second region of the substrate, the isolation structure extending through the second nitride semiconductor layer and the first nitride semiconductor layer to the substrate;
forming a first source contact and a first drain contact on the second nitride semiconductor layer on the first region of the substrate;
forming a first gate structure on the second nitride semiconductor layer and between the first source contact and the first drain contact;
forming a second source contact and a second drain contact on the second nitride semiconductor layer on the second region of the substrate; and
forming a second gate structure on the second nitride semiconductor layer and between the second source contact and the second drain contact; and
forming a first conductive wire on the first source contact and the second drain contact, wherein the first conductive wire connects the first source contact and the second drain contact.

Embodiment 3-17: The method of any of the preceding embodiments, further comprising forming a first conductive via connecting the first conductive wire to the first doped region.

Embodiment 3-18: The method of any of the preceding embodiments, further comprising forming a second conductive wire on the second source contact and a second conductive via connecting the second conductive wire to the second doped region.

Embodiment 3-19: The method of any of the preceding embodiments, further comprising forming a dielectric layer on the second nitride semiconductor layer, wherein the dielectric layer covers a portion of a lateral surface of the first conductive wire.

Embodiment 3-20: The method of any of the preceding embodiments, further comprising forming a dielectric layer on the second nitride semiconductor layer, wherein the dielectric layer covers a portion of a lateral surface of the second conductive wire.

Embodiment 3-21: A semiconductor device, comprising:
a substrate having a first region and a second region;
a first doped region in the first region of the substrate, wherein the first doped region has opposite polarity to the substrate;
a second doped region in the second region of the substrate, wherein the second doped region has opposite polarity to the substrate;
a first nitride semiconductor layer on the substrate;
a second nitride semiconductor layer on the first nitride semiconductor layer and having a band gap greater than a band gap of the first nitride semiconductor layer;
an isolation structure surrounding the first doped region;
a first source contact and a first drain contact on the second nitride semiconductor layer on the first region of the substrate; and
a first gate structure on the second nitride semiconductor layer and between the first source contact and the first drain contact;
a second source contact and a second drain contact on the second nitride semiconductor layer on the second region of the substrate; and
a second gate structure on the second nitride semiconductor layer and between the second source contact and the second drain contact; and
a first conductive wire disposed on and connecting the first source contact and the second drain contact,
wherein a projection of the first conductive wire perpendicular to an upper surface of the substrate overlaps the isolation structure, the upper surface facing the first nitride semiconductor layer.

Embodiment 3-22: The semiconductor device of any of the preceding embodiments, wherein the isolation structure extends through the second nitride semiconductor layer and the first nitride semiconductor layer to the substrate

Embodiment 3-23: The semiconductor device of any of the preceding embodiments, further comprising a first conductive via connecting the first conductive wire to the first doped region.

Embodiment 3-24: The semiconductor device of any of the preceding embodiments, further comprising a second conductive wire on the second source contact and a second conductive via connecting the second conductive wire to the second doped region.

Embodiment 3-25: The semiconductor device of any of the preceding embodiments, further comprising a dielectric layer on the second nitride semiconductor layer, wherein the dielectric layer covers a portion of a lateral surface of the first conductive wire.

Embodiment 4-1: A semiconductor device, comprising:
a substrate having a first region and a second region;
a doped semiconductor layer on the first region and the second region of the substrate, wherein the doped semiconductor layer has opposite polarity to the substrate;
a first nitride semiconductor layer on the doped semiconductor layer;
a second nitride semiconductor layer on the first nitride semiconductor layer and having a band gap greater than a band gap of the first nitride semiconductor layer;
an isolation structure disposed between the first region and the second region of the substrate and extending through the second nitride semiconductor layer, the first nitride semiconductor layer and the doped semiconductor layer to the substrate;
a first source contact and a first drain contact on the second nitride semiconductor layer on the first region of the substrate;
a first gate structure on the second nitride semiconductor layer and between the first source contact and the first drain contact;
a second source contact and a second drain contact on the second nitride semiconductor layer on the second region of the substrate;
a second gate structure on the second nitride semiconductor layer and between the second source contact and the second drain contact; and
a first conductive wire disposed on and connecting the first source contact and the second drain contact.

Embodiment 4-2: The semiconductor device of any of the preceding embodiments, wherein the first source contact is between the first drain contact and the second drain contact.

Embodiment 4-3: The semiconductor device of any of the preceding embodiments, wherein the second drain contact is between the first source contact and the second source contact.

Embodiment 4-4: The semiconductor device of any of the preceding embodiments, further comprising a first conductive via connecting the first conductive wire to the doped semiconductor layer on the first region of the substrate.

Embodiment 4-5: The semiconductor device of any of the preceding embodiments, wherein the first conductive via is between the first contact source and the isolation structure.

Embodiment 4-6: The semiconductor device of any of the preceding embodiments, further comprising a second conductive wire on the second source contact and a second conductive via connecting the second conductive wire to the doped semiconductor layer on the second region of the substrate.

Embodiment 4-7: The semiconductor device of any of the preceding embodiments, wherein the second conductive wire has a lower surface facing the substrate and connected to the second source contact and the second conductive via.

Embodiment 4-8: The semiconductor device of any of the preceding embodiments, wherein the second source contact is between the second gate structure and the second conductive via.

Embodiment 4-9: The semiconductor device of any of the preceding embodiments, further comprising a dielectric layer on the second nitride semiconductor layer, wherein the dielectric layer covers a portion of a lateral surface of the first conductive wire.

Embodiment 4-10: The semiconductor device of any of the preceding embodiments, further comprising a first conductive via connected to the first conductive wire, wherein the first conductive via extends through a portion of the dielectric layer, the second nitride semiconductor layer and the first nitride semiconductor layer to the doped semiconductor layer on the first region of the substrate.

Embodiment 4-11: The semiconductor device of any of the preceding embodiments, further comprising a second conductive wire on the second source contact and a second conductive via connected to the second conductive wire, wherein the second conductive via extends through a portion of the dielectric layer, the second nitride semiconductor layer and the first nitride semiconductor layer to the doped semiconductor layer on the second region of the substrate.

Embodiment 4-12: The semiconductor device of any of the preceding embodiments, wherein the dielectric layer covers a portion of a lateral surface of the second conductive wire.

Embodiment 4-13: The semiconductor device of any of the preceding embodiments, wherein a portion of the dielectric layer is between the second source contact and the second conductive via.

Embodiment 4-14: The semiconductor device of any of the preceding embodiments, wherein the first gate structure comprises a first doped nitride semiconductor element on the second nitride semiconductor layer and a first gate contact on the first doped nitride semiconductor element.

Embodiment 4-15: The semiconductor device of any of the preceding embodiments, wherein the second gate structure comprises a second doped nitride semiconductor element on the second nitride semiconductor layer and a second gate contact on the second doped nitride semiconductor element.

Embodiment 4-16: A method of manufacturing a semiconductor device, comprising:
providing a substrate having a first region and a second region;
forming a doped semiconductor layer on the first region and the second region of the substrate, wherein the doped semiconductor layer has opposite polarity to the substrate;
forming a first nitride semiconductor layer on the doped semiconductor layer;
forming a second nitride semiconductor layer on the first nitride semiconductor layer, wherein the second nitride semiconductor layer has a band gap greater than a band gap of the first nitride semiconductor layer;
forming an isolation structure between the first region and the second region of the substrate, the isolation structure extending through the second nitride semiconductor layer, the first nitride semiconductor layer and the doped semiconductor layer to the substrate;
forming a first source contact and a first drain contact on the second nitride semiconductor layer on the first region of the substrate;
forming a first gate structure on the second nitride semiconductor layer and between the first source contact and the first drain contact;
forming a second source contact and a second drain contact on the second nitride semiconductor layer on the second region of the substrate; and
forming a second gate structure on the second nitride semiconductor layer and between the second source contact and the second drain contact; and
forming a first conductive wire on the first source contact and the second drain contact, wherein the first conductive wire connects the first source contact and the second drain contact.

Embodiment 4-17: The method of any of the preceding embodiments, further comprising forming a first conductive via connecting the first conductive wire to the doped semiconductor layer on the first region of the substrate.

Embodiment 4-18: The method of any of the preceding embodiments, further comprising forming a second conductive wire on the second source contact and a second conductive via connecting the second conductive wire to the doped semiconductor layer on the second region of the substrate.

Embodiment 4-19: The method of any of the preceding embodiments, further comprising forming a dielectric layer on the second nitride semiconductor layer, wherein the dielectric layer covers a portion of a lateral surface of the first conductive wire.

Embodiment 4-20: The method of any of the preceding embodiments, further comprising forming a dielectric layer on the second nitride semiconductor layer, wherein the dielectric layer covers a portion of a lateral surface of the second conductive wire.

Embodiment 4-21: A semiconductor device, comprising:
a substrate having a first region and a second region;
a doped semiconductor layer on the first region and the second region of the substrate, wherein the doped semiconductor layer has opposite polarity to the substrate;
a first nitride semiconductor layer on the doped semiconductor layer;
a second nitride semiconductor layer on the first nitride semiconductor layer and having a band gap greater than a band gap of the first nitride semiconductor layer;
an isolation structure surrounding the first region of the substrate;
a first source contact and a first drain contact on the second nitride semiconductor layer on the first region of the substrate;
a first gate structure on the second nitride semiconductor layer and between the first source contact and the first drain contact;
a second source contact and a second drain contact on the second nitride semiconductor layer on the second region of the substrate;
a second gate structure on the second nitride semiconductor layer and between the second source contact and the second drain contact; and
a first conductive wire disposed on and connecting the first source contact and the second drain contact,
wherein a projection of the first conductive wire perpendicular to an upper surface of the substrate overlaps the isolation structure, the upper surface facing the first nitride semiconductor layer.

Embodiment 4-22: The semiconductor device of any of the preceding embodiments, wherein the isolation structure extends through the second nitride semiconductor layer, the first nitride semiconductor layer and the doped semiconductor layer to the substrate.

Embodiment 4-23: The semiconductor device of any of the preceding embodiments, further comprising a first conductive via connecting the first conductive wire to the doped semiconductor layer on the first region of the substrate.

Embodiment 4-24: The semiconductor device of any of the preceding embodiments, further comprising a second conductive wire on the second source contact and a second conductive via connecting the second conductive wire to the doped semiconductor layer on the second region of the substrate.

Embodiment 4-25: The semiconductor device of any of the preceding embodiments, further comprising a dielectric layer on the second nitride semiconductor layer, wherein the dielectric layer covers at least a portion of a lateral surface of the first conductive wire.

As used herein, spatially relative terms, such as “beneath,” “below,” “lower,” “above,” “upper,” “higher.” “left.” “right” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As used herein, the terms “approximately.” “substantially,” “substantial” and “about” are used to describe and account for small variations. When used in conduction with an event or circumstance, the terms can refer to instances in which the event of circumstance occurs precisely as well as instances in which the event or circumstance occurs to a close approximation. As used herein with respect to a given value or range, the term “about” generally means within +10%, +5%, +1%, or +0.5% of the given value or range. Ranges can be expressed herein as from one endpoint to another endpoint or between two endpoints. All ranges disclosed herein are inclusive of the endpoints, unless specified otherwise. The term “substantially coplanar” can refer to two surfaces within micrometers (μm) of lying along a same plane, such as within 10 μm, within 5 μm, within 1 μm, or within 0.5 μm of lying along the same plane. When referring to numerical values or characteristics as “substantially” the same, the term can refer to the values lying within +10%, +5%, +1%, or +0.5% of an average of the values.

The foregoing outlines features of several embodiments and detailed aspects of the present disclosure. The embodiments described in the present disclosure may be readily used as a basis for designing or modifying other processes and structures for carrying out the same or similar purposes and/or achieving the same or similar advantages of the embodiments introduced herein. Such equivalent constructions do not depart from the spirit and scope of the present disclosure, and various changes, substitutions, and alterations may be made without departing from the spirit and scope of the present disclosure.

1. A semiconductor device, comprising:
a substrate;
a first nitride semiconductor layer on the substrate;
a second nitride semiconductor layer on the first nitride semiconductor layer and having a band gap greater than a band gap of the first nitride semiconductor layer;
a drain contact on the second nitride semiconductor layer;
a source contact on the second nitride semiconductor layer;
a common contact on the second nitride semiconductor layer and between the drain contact and the source contact;
a first gate structure on the second nitride semiconductor layer and between the drain contact and the common contact;
a second gate structure on the second nitride semiconductor layer and between the common contact and the source contact;
a conductive wire on the source contact;
a dielectric layer on the second nitride semiconductor layer and covering a portion of a lateral surface of the conductive wire; and
a conductive via connected to the conductive wire,
wherein the conductive via extends through a portion of the dielectric layer, the second nitride semiconductor layer, and the first nitride semiconductor layer to the substrate.

2. The semiconductor device of claim 1, wherein the conductive wire has a lower surface facing the substrate and extending beyond the source contact and the conductive via is connected to the lower surface of the conductive wire.

3. The semiconductor device of claim 1, wherein the dielectric layer covers a portion of the lower surface of the conductive wire.

4. The semiconductor device of claim 1, wherein a portion of the dielectric layer is between the source contact and the conductive via.

5. The semiconductor device of claim 1, wherein a portion of the dielectric layer is between the conductive wire and the second nitride semiconductor layer.

6. The semiconductor device of claim 1, further comprising a second conductive wire on the common contact, wherein the dielectric layer covers at least a portion of the second conductive wire.

7. The semiconductor device of claim 1, wherein a shortest distance between the first gate structure and the common contact is smaller than a shortest distance between the first gate structure and the drain contact.

8. The semiconductor device of claim 1, wherein a shortest distance between the second gate structure and the common contact is greater than a shortest distance between the second gate structure and the source contact.

9. The semiconductor device of claim 1, wherein a shortest distance between the first gate structure and the common contact is smaller than a shortest distance between the second gate structure and the common contact.

10. The semiconductor device of claim 1, wherein the source contact is between the second gate structure and the conductive via.

11. The semiconductor device of claim 1, wherein the conductive wire is between the source contact and the conductive via.

12. The semiconductor device of claim 1, wherein the first gate structure comprises a doped nitride semiconductor element on the second nitride semiconductor layer and a gate contact on the doped nitride semiconductor element.

13. The semiconductor device of claim 1, wherein the second gate structure comprises a doped nitride semiconductor element on the second nitride semiconductor layer and a gate contact on the doped nitride semiconductor element.

14. A method of manufacturing a semiconductor device, comprising:
providing a substrate;
forming a first nitride semiconductor layer on the substrate;
forming a second nitride semiconductor layer on the first nitride semiconductor layer, wherein the second nitride semiconductor layer has a band gap greater than a band gap of the first nitride semiconductor layer;
forming a drain contact and a source contact on the second nitride semiconductor layer;
forming a common contact on the second nitride semiconductor layer and between the drain contact and the source contact;
forming a first gate structure on the second nitride semiconductor layer and between the drain contact and the common contact;
forming a second gate structure on the second nitride semiconductor layer and between the common contact and the source contact;
forming a conductive wire on the source contact;
forming a dielectric layer on the second nitride semiconductor layer, wherein the dielectric layer covers a portion of a lateral surface of the conductive wire; and
forming a conductive via connected to the conductive wire, wherein the conductive via extends through a portion of the dielectric layer, the second nitride semiconductor layer, and the first nitride semiconductor layer to the substrate.

15. The method of claim 14, wherein the conductive wire has a lower surface facing the substrate and extending beyond the source contact and the conductive via is connected to the lower surface of the conductive wire.

16. The method of claim 14, wherein the dielectric layer covers a portion of the lower surface of the conductive wire.

17. The method of claim 14, wherein a portion of the dielectric layer is between the source contact and the conductive via.

18. The method of claim 14, further comprising:
forming a second conductive wire on the common contact, wherein the dielectric layer covers at least a portion of the second conductive wire.

19. The method of claim 14, wherein a shortest distance between the first gate structure and the common contact is smaller than a shortest distance between the first gate structure and the drain contact.

20. The method of claim 14, wherein a shortest distance between the second gate structure and the common contact is greater than a shortest distance between the second gate structure and the source contact.

21. A semiconductor device, comprising:
a substrate;
a first nitride semiconductor layer on the substrate;
a second nitride semiconductor layer on the first nitride semiconductor layer and having a band gap greater than a band gap of the first nitride semiconductor layer;
a drain contact on the second nitride semiconductor layer;
a source contact on the second nitride semiconductor layer;
a common contact on the second nitride semiconductor layer and between the drain contact and the source contact;
a first gate structure on the second nitride semiconductor layer and between the drain contact and the common contact; and
a second gate structure on the second nitride semiconductor layer and between the common contact and the source contact,
wherein the source contact is electrically connected to the substrate through a conductive via, and a shortest distance between the first gate structure and the common contact is smaller than a shortest distance between the second gate structure and the common contact.

22. The semiconductor device of claim 21, wherein the shortest distance between the first gate structure and the common contact is smaller than a shortest distance between the first gate structure and the drain contact.

23. The semiconductor device of claim 21, wherein the shortest distance between the second gate structure and the common contact is greater than a shortest distance between the second gate structure and the source contact.

24. The semiconductor device of claim 21, further comprising a dielectric layer on the second nitride semiconductor layer, wherein the dielectric layer covers a portion of a lateral surface of the conductive via, the lateral surface facing the source contact or the drain contact.

25. The semiconductor device of claim 21, wherein a portion of the dielectric layer is between the source contact and the conductive via.

26. The semiconductor device of claim 21, further comprising a conductive wire on the source contact, wherein the conductive via is connected to the conductive wire.

27. The semiconductor device of claim 21, wherein the conductive wire has a lower surface facing the substrate and extending beyond the source contact and the conductive via is connected to the lower surface of the conductive wire.
